(19) United States
(12) Patent Application Publication
(10) Pub. No.: US 2021/0294529 A1
(43) Pub. Date: Sep. 23, 2021

(54) STORAGE DEVICE AND METHOD

(71) Applicant: Kioxia Corporation, Tokyo (JP)

(72) Inventor: Kensuke MINATO, Kawasaki (JP)

(73) Assignee: Kioxia Corporation, Tokyo (JP)

(21) Appl. No.: 17/018,817

(22) Filed: Sep. 11, 2020

(30) Foreign Application Priority Data
Mar. 19, 2020 (JP) 2020-049111

(51) Int. Cl. G06F 3/06; G11C 7/10

(52) U.S. Cl. CPC G06F 3/0659; G11C 7/106; G06F 3/0653; G06F 3/0604; G06F 3/0679; G06F 3/0629; G11C 7/1087

(57) ABSTRACT

According to one embodiment, a storage device comprises a memory cell, a control circuit, and a command register. The memory cell array is configured to store data. The control circuit is configured to process the data stored in the memory cell array in accordance with a command transmitted from a controller. The command register is configured to store a first command and a second command transmitted from the controller.

### CROSS-REFERENCE TO RELATED APPLICATIONS

This application is based upon and claims the benefit of priority from Japanese Patent Application No. 2020-049111, filed Mar. 19, 2020, the entire contents of which are incorporated herein by reference.

### FIELD

Embodiments described herein relate generally to a storage device and a method.

### BACKGROUND

A storage device includes a nonvolatile semiconductor memory (hereinafter referred to as a nonvolatile memory) and a controller that receives data from the nonvolatile memory. The controller transmits a command to the nonvolatile memory through a signal line. The nonvolatile memory transmits data to the controller through the same signal line in response to the command. The command transmitted to the nonvolatile memory causes an overhead on data reading by the controller.

### BRIEF DESCRIPTION OF THE DRAWINGS

FIG. 1 is a block diagram illustrating an example of an information processing system including a storage device according to the first embodiment.

FIG. 2 is a block diagram illustrating an example of a nonvolatile memory according to the first embodiment.

FIG. 3 is a block diagram illustrating an example of a command register according to the first embodiment.

FIG. 4 is an equivalent circuit diagram of an example of a memory cell array of the nonvolatile memory according to the first embodiment.

FIG. 5 is a block diagram illustrating an example of a sense amplifier and a data cache according to the first embodiment.

FIG. 6 is a timing chart illustrating an example of the cache read operation according to the first embodiment.

FIG. 7A is a diagram illustrating an example of a read command sequence according to the first embodiment.

FIG. 7B is a diagram illustrating an example of the cache read command sequence according to the first embodiment.

FIG. 7C is a diagram illustrating an example of a data output command sequence according to the first embodiment.

FIG. 8A is a diagram illustrating an example of a data transfer state in the nonvolatile memory at timing t2 in FIG. 6.

FIG. 8B is a diagram illustrating an example of a data transfer state in the nonvolatile memory at timing t4 in FIG. 6.

FIG. 8C is a diagram illustrating an example of a data transfer state in the nonvolatile memory at timing t7 in FIG. 6.

FIG. 9A is a diagram illustrating an example of a data transfer state in the nonvolatile memory at timing t9 in FIG. 6.

FIG. 9B is a diagram illustrating an example of a data transfer state in the nonvolatile memory at timing t12 in FIG. 6.

FIG. 10 is a block diagram illustrating an example of a storage device that performs a bank interleave operation with four banks, which is another example of a storage device to which the first embodiment is applied.

FIG. 11 is a timing chart illustrating an example of the cache read operation according to the first embodiment in the storage device in FIG. 10.

FIG. 12 is a block diagram illustrating an example of a nonvolatile memory according to a second embodiment.

FIG. 13 is a block diagram illustrating an example of an address register according to the second embodiment.

FIG. 14 is a timing chart illustrating an example of the cache read operation according to the second embodiment.

FIG. 15 is a timing chart illustrating an example of the cache read operation according to a third embodiment.

FIG. 16 is a timing chart illustrating an example of the cache read operation according to a fourth embodiment.

FIG. 17A is a diagram illustrating an example of the cache read command sequence for a plane A in FIG. 16.

FIG. 17B is a diagram illustrating an example of the cache read command sequence for a plane B in FIG. 16.

FIG. 18 is a diagram illustrating another example of the cache read command sequence for the plane A in FIG. 16.

### DETAILED DESCRIPTION

Hereinafter, embodiments will be described with reference to the drawings. The following description is given on examples of a device and a method for implementing the technical idea of the embodiment. Thus, the technical idea of the embodiment is not limited to the structure, shape, arrangement, and material of the components described below. Modifications that can be easily conceived by those skilled in the art are naturally included in the scope of the disclosure. In order to make the description clearer, in the drawings, the size, thickness, plane size, shape, or the like of each element may be changed from those in the actual embodiment to be schematically represented. In a plurality of drawings, elements having different dimensional relationships or ratios may be included. In a plurality of drawings, corresponding elements may be given the same reference numerals, and redundant description may be omitted. Some elements may be given a plurality of names, but these example names are merely examples, and thus do not exclude the possibility of giving other names to these elements. Furthermore, the possibility of giving other names is also not excluded for elements not given a plurality of names. In the following description, “connection” is not limited to direct connection and may indicate indirect connection with another element provided in between.

A plurality of elements that have the same function are denoted with reference numerals having a number/alphabet provided at the end to be distinguished from each other, but may also be denoted with reference numerals with the number/alphabet at the end omitted when they do not need to be distinguished from each other.

In general, according to one embodiment, a storage device comprises a memory cell, a control circuit, and a command register. The memory cell array is configured to store data. The control circuit is configured to process the data stored in the memory cell array in accordance with a command transmitted from a controller. The command register is configured to store a first command and a second command transmitted from the controller.

### First Embodiment

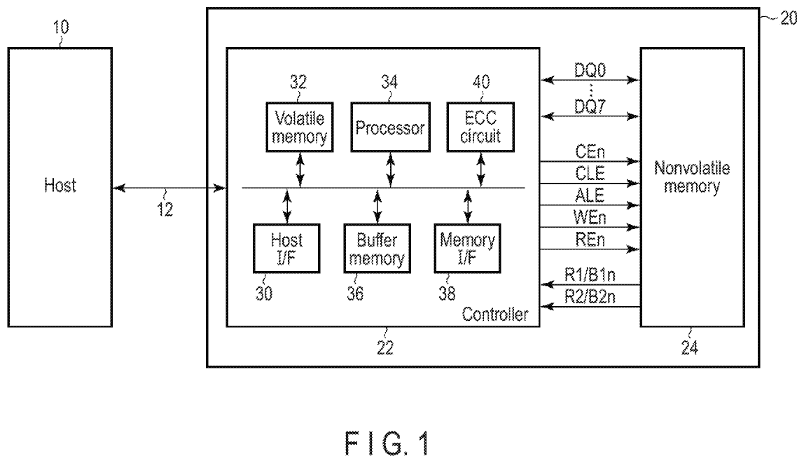

FIG. 1 is a block diagram illustrating an example of an information processing system including a storage device according to an embodiment. The information processing system includes a host 10 and a storage device 20.

The host 10 is an external information processing device that writes data to the storage device 20. Alternatively, the host 10 is an external information processing device that reads data from the storage device 20. The host 10 requests the storage device 20 for writing, reading, or erasing of data. The host 10 may be a server or a personal computer.

The storage device 20 includes a controller 22 and a nonvolatile memory 24. The nonvolatile memory 24 is an example of the storage device according to the embodiment. The storage device 20 is connected to the host 10 via a controller bus 12. The controller bus 12 may be implemented with a cable. Alternatively, the controller bus 12 may be implemented wirelessly. The storage device 20 may be a memory card or a solid state drive (SSD). The memory card may be a secure digital (SD) (registered trademark) card.

The controller 22 controls the nonvolatile memory 24. The controller 22 transmits a command to the nonvolatile memory 24 to instruct reading, writing, erasing, and the like of data. The controller 22 manages a memory space of the nonvolatile memory 24. The controller 22 may be implemented with a circuit such as a System-on-chip (SoC). The controller 22 is connected to the host 10 through the controller bus 12.

The nonvolatile memory 24 is a semiconductor memory that can store data even without power supply. The nonvolatile memory 24 may be a NAND type flash memory of a two-dimensional structure, or may be a NAND type flash memory of a three-dimensional structure. The nonvolatile memory 24 is not limited to the NAND type flash memory, and may be a NOR type flash memory or other nonvolatile semiconductor memories. The nonvolatile memory 24 is connected to the controller 22 using a memory bus. The nonvolatile memory 24 operates based on the command from the controller 22.

The memory bus transmits I/O signals DQ0 to DQ7, a chip enable signal CEn, a command latch enable signal CLE, an address latch enable signal ALE, a write enable signal WEn, a read enable signal REn, a memory cell ready/busy signal R1/B1n, and a cache ready/busy signal R2/B2n. The signals with “n” added to the end of the reference numerals are asserted at a low level. The signals without “n” at the end of the reference numerals are asserted at a high level.

The I/O signals DQ0 to DQ7 (may be also written as DQ[7:0]) are signals transmitted bidirectionally between the controller 22 and the nonvolatile memory 24. The I/O signals DQ0 to DQ7 include data, a command, and the like. With the command and data thus transmitted between the controller 22 and the nonvolatile memory 24 through the same signal line, the command transmission causes an overhead on the data transmission.

The chip enable signal CEn is a signal for enabling the nonvolatile memory 24.

The command latch enable signal CLE is a signal indicating that the I/O signal DQ is a command.

The address latch enable signal ALE is a signal indicating that the I/O signal DQ is an address.

The write enable signal WEn is a signal for loading the received I/O signal DQ into the nonvolatile memory 24. The write enable signal WEn is asserted at the low level every time a command, an address, data, and the like are received from the controller 22. Thus, each time the write enable signal WEn is toggled, the I/O signal DQ is loaded into the nonvolatile memory 24.

The read enable signal REn is a signal enabling the controller 22 to read data from the nonvolatile memory 24. The read enable signal REn is asserted at the low level. Thus, the nonvolatile memory 24 transmits the I/O signal DQ to the controller 22 based on the read enable signal REn toggled.

The memory cell ready/busy signal R1/B1n is a signal indicating whether the memory cell array in the nonvolatile memory 24 is busy or ready. When the memory cell array is busy, the nonvolatile memory 24 cannot receive a command related to data transfer of the memory cell array. When the memory cell array is ready, the nonvolatile memory 24 can receive a command related to the data transfer of the memory cell array. For example, when the memory cell array is busy, the signal level of the memory cell ready/busy signal R1/B1n is set to the low level. When the memory cell array is ready, the signal level of the memory cell ready/busy signal R1/B1n is set to the high level.

The cache ready/busy signal R2/B2n is a signal indicating whether a data cache in the nonvolatile memory 24 is busy or ready. When the data cache is busy, the nonvolatile memory 24 cannot receive a command related to data transfer of the data cache. When the data cache is ready, the nonvolatile memory 24 can receive the command related to the data transfer of the data cache. For example, when the data cache is busy, the signal level of the cache ready/busy signal R2/B2n is set to the low level. When the data cache is ready, the signal level of the cache ready/busy signal R2/B2n is set to the high level.

The controller 22 includes a host interface circuit (hereinafter, referred to as host I/F) 30, a volatile memory 32, a processor 34, a buffer memory 36, a memory interface circuit (hereinafter, referred to as memory I/F) 38, an error checking and correcting (ECC) circuit 40, and the like.

The host I/F 30 controls communications between the host 10 and the controller 22. The host I/F 30 transfers a request and data received from the host 10 to the processor 34 and the buffer memory 36. The host I/F 30 transfers data in the buffer memory 36 to the host 10 based on a request from the processor 34.

The volatile memory 32 is used as a work area for the processor 34. The volatile memory 32 stores firmware, various management tables, and the like for managing the nonvolatile memory 24. The volatile memory 32 may be a Double Data Rate 3 Low voltage (DDR3L) standard Dynamic Random Access Memory (DRAM). Instead of the volatile memory 32, a part of the DRAM provided to the host 10 may be used as a host memory buffer (HMB).

The processor 34 controls operations of the controller 22. The processor 34 issues various commands in response to a request from the host 10. The processor 34 transmits a command to the nonvolatile memory 24. Upon receiving a write request from the host 10, the processor 34 may transmit a write command to the nonvolatile memory 24. For reading and erasing, the processor 34 may transmit a command, corresponding to the request from the host 10, to the nonvolatile memory 24. The processor 34 also executes various types of processing such as wear leveling for managing the nonvolatile memory 24. The processor 34 executes various mathematical operations. The processor 34 may execute data encryption processing, randomization processing, and the like.

The buffer memory 36 may be SRAM. The buffer memory 36 temporarily stores data transmitted and received between the controller 22 and the nonvolatile memory 24. The buffer memory 36 temporarily stores data transmitted and received between the controller 22 and the host 10. The buffer memory 36 temporarily stores data generated in the controller 22.

The memory I/F 38 controls communications between the nonvolatile memory 24 and the controller 22. The memory I/F 38 transfers the request received from the processor 34 to the nonvolatile memory 24. For writing, the memory I/F 38 transfers the write data in the buffer memory 36, to the nonvolatile memory 24. For reading, the memory I/F 38 transfers the data read from the nonvolatile memory 24, to the buffer memory 36.

The ECC circuit 40 executes ECC processing of data.

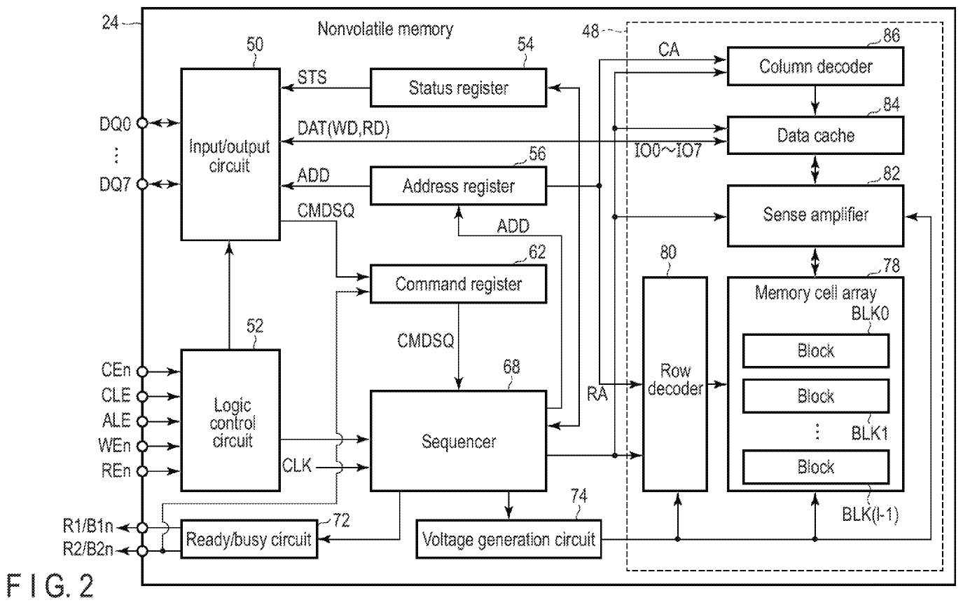

FIG. 2 is a block diagram illustrating a detailed configuration of the nonvolatile memory 24 according to the embodiment.

The nonvolatile memory 24 includes an input/output circuit 50, a logic control circuit 52, a status register 54, an address register 56, a command register 62, a sequencer 68, a ready/busy circuit 72, a voltage generation circuit 74, a memory cell array 78, a row decoder 80, a sense amplifier 82, a data cache 84, a column decoder 86, and the like.

The input/output circuit 50 controls input/output of the I/O signal DQ to and from the controller 22. The input/output circuit 50 and the data cache 84 are connected to each other via a data bus. The data bus may include eight data lines 100 to 107 respectively corresponding to the I/O signals DQ0 to DQ7. The number of data lines 10 is not limited to eight and can be set to be any number. The input/output circuit 50 includes an input circuit and an output circuit. The input circuit transmits data DAT (write data WD) received from the controller 22, to the data cache 84. The input circuit transmits ae command sequence CMDSQ received from the controller 22, to the command register 62. The command sequence CMDSQ includes a plurality of commands CMD and a plurality of addresses ADD. An address ADD includes a row address RA and a column address CA. The output circuit transmits status information STS received from the status register 54, to the controller 22. The output circuit transmits data DAT (read data RD) received from the data cache 84, to the controller 22. The output circuit transmits the address ADD received from the address register 56, to the controller 22.

The logic control circuit 52 receives the chip enable signal CEn, the command latch enable signal CLE, the address latch enable signal ALE, the write enable signal WEn, the read enable signal REn, and the like from the controller 22. The logic control circuit 52 controls the input/output circuit 50 and the sequencer 68 according to the received signal.

The status register 54 may temporarily store the status information STS in data write, data read, and erase operations. With the status information STS, the controller 22 is notified of whether the operation has been completed properly.

The address register 56 temporarily stores the address ADD received from the sequencer 68. The address register 56 transfers the row address RA to the row decoder 80 and the column address CA to the column decoder 86.

The command register 62 temporarily stores the command sequence CMDSQ received from the input/output circuit 50.

The sequencer 68 controls the operation of the nonvolatile memory 24. The sequencer 68 sequentially receives commands and addresses included in the command sequence CMDSQ output from the command register 62. The sequencer 68 may control the status register 54, the ready/busy circuit 72, the voltage generation circuit 74, the row decoder 80, the sense amplifier 82, the data cache 84, the column decoder 86, and the like according to the received command. Thus, the sequencer 68 executes a write operation, a read operation, an erase operation, and the like. For example, a clock signal CLK is supplied to the sequencer 68. The clock signal CLK is transmitted from the controller 22. Alternatively, the clock signal CLK is generated based on another clock signal from the controller 22. Upon receiving an address included in the command sequence CMDSQ, the sequencer 68 transfers the address ADD to the address register 56.

The ready/busy circuit 72 controls the signal levels of the memory cell ready/busy signal R1/B1n and the cache ready/busy signal R2/B2n under the control of the sequencer 68 according to the operation status of the storage device 20. The ready/busy circuit 72 transmits the memory cell ready/busy signal R1/B1n and the cache ready/busy signal R2/B2n to the controller 22. The ready/busy circuit 72 also transmits the cache ready/busy signal R2/B2n to the command register 62.

The voltage generation circuit 74 generates voltages used for the write operation, the read operation, and the erase operation under the control of the sequencer 68. The voltage generation circuit 74 supplies the generated voltages to the memory cell array 78, the row decoder 80, the sense amplifier 82, and the like. The row decoder 80 and the sense amplifier 82 apply the voltages supplied from the voltage generation circuit 74, to memory cells of the memory cell array 78.

The memory cell array 78 stores data. The structure of the memory cell array 78 may be a two-dimensional structure with the memory cells two dimensionally arranged or a three-dimensional structure with the memory cells three-dimensionally arranged. The memory cell array 78 includes a plurality of blocks BLK0, BLK1, . . . , BLK(1-1)) (1 is an integer that is equal to or larger than 2).

The row decoder 80 decodes the row address RA. The row decoder 80 selects any of the blocks BLK and any of string units SU based on the decoding result.

In the read operation, the sense amplifier 82 amplifies the level of the data read from the memory cell array 78 to a level detectable as the read data RD. The sense amplifier 82 outputs the read data RD to the data cache 84. In the write operation, the sense amplifier 82 outputs the write data WD to the memory cell array 78. The sense amplifier 82 may include a plurality of sense amplifier units SAU.

The data cache 84 includes a plurality of latch circuits. The latch circuit stores the write data WD and the read data RD. For example, for writing, the data cache 84 temporarily stores the write data WD received from the input/output circuit 50. The data cache 84 outputs the temporarily stored data to the sense amplifier 82. For reading, the data cache 84 temporarily stores the read data RD received from the sense amplifier 82. The data cache 84 outputs the temporarily stored data to the input/output circuit 50.

The column decoder 86 decodes the column address CA. The column decoder 86 selects a latch circuit in the data cache 84 in accordance with the decoding result.

The nonvolatile memory 24 may include a unit of control referred to as a plane 46. A plane 48 may include the memory cell array 78, the row decoder 80, the sense amplifier 82, the data cache 84, and the column decoder 86. In FIG. 2, the nonvolatile memory 24 includes a plane 48. It should be noted that the nonvolatile memory 24 may include two or more planes 48. When the nonvolatile memory 24 includes a plurality of planes 48, the planes 48 can implement different operations at different timings under the control of the sequencer 68.

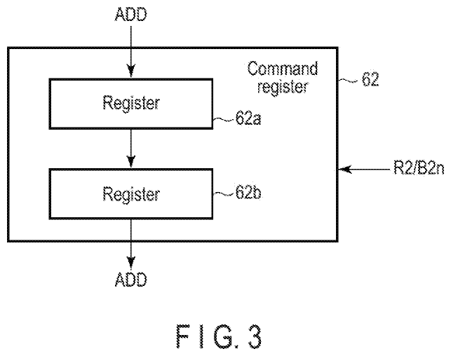

FIG. 3 is a block diagram illustrating an example of a configuration of the command register 62 according to the embodiment. The command register 62 receives the command sequence CMDSQ from the input/output circuit 50. The command register 62 also receives the cache ready/busy signal R2/B2n from the ready/busy circuit 72. The command register 62 includes a register 62a and a register 62b. The register 62a stores a single command sequence. The register 62b stores another single command sequence.

The command sequence CMDSQ transmitted from the input/output circuit 50 is input to the register 62a. When the cache ready/busy signal R2/B2n is at the high level, the register 62a transfers the input command sequence to the register 62b instead of storing it. The register 62b stores the transferred command sequence. When the cache ready/busy signal R2/B2n is at the low level, the register 62a stores the input command sequence. When the cache ready/busy signal R2/B2n changes from the low level to the high level, the register 62a transfers the stored command sequence to the register 62b. The register 62b stores the transferred command sequence. The register 62b sequentially outputs a plurality of commands and a plurality of addresses included in the command sequence stored therein, to the sequencer 68.

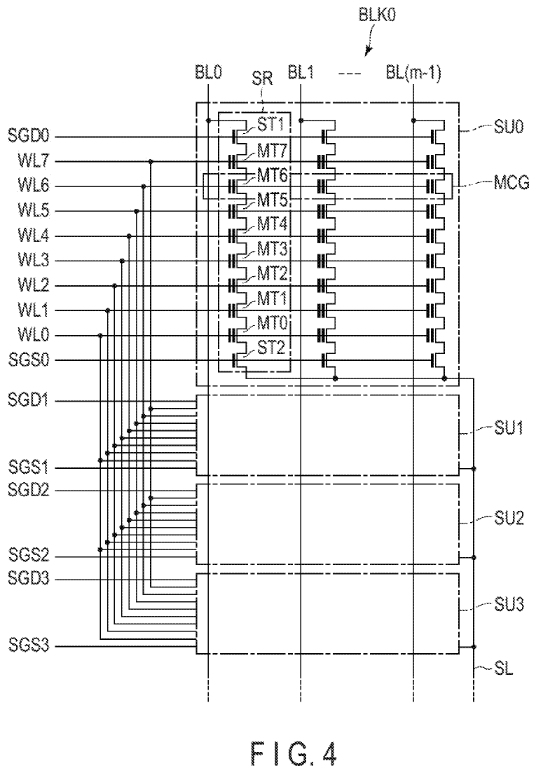

FIG. 4 is an equivalent circuit diagram of an example of the memory cell array 78 of the nonvolatile memory 24 according to the embodiment. The memory cell array 78 includes a plurality of blocks BLK0, BLK1, . . . , BLK(1-1). In the following description of this specification, the nonvolatile memory 24 is assumed to be a NAND type flash memory. Of the blocks BLK0 to BLK(1-1), FIG. 4 only illustrates the configuration of the block BLK0. Although not illustrated, the other blocks BLK1 to BLK(1-1) have the same configuration as the block BLK0.

The block BLK0 includes a plurality of string units SU. The block BLK0 includes four string units SU0 to SU3. Each of the string units SU0 to SU3 includes a plurality of NAND strings SR. Each of the NAND strings SR includes a plurality of memory cells MT and two types of select transistors ST1 and ST2. The number of memory cells MT may be eight (MT0 to MT7). The number of each of the two types of select transistors ST1 and ST2 may be any number.

A memory cell MT includes a control gate and a charge storage layer. Thus, the memory cell MT stores data in a nonvolatile manner. The memory cell MT may be of a MONOS type using an insulating layer (for example, a silicon nitride film) as the charge storage layer, or of a floating gate type using a conductive layer (for example, a silicon film) as the charge storage layer.

The plurality of memory cells MT are connected in series between the source of the select transistor ST1 and the drain of the select transistor ST2. The current paths of the plurality of memory cells MT are connected in series. The first terminal (for example, drain) of the current path of the memory cell. MT7 is connected to the second terminal (for example, source) of the current path of the select transistor ST1. The second terminal (for example, source) of the current path of the memory cell MT0 is connected to the first terminal (for example, drain) of the current path of the select transistor ST2.

The gates of the plurality of select transistors ST1 in the string units SU0 to SU3 are respectively connected to select gate lines SGD0 to SGD3. The gates of the plurality of select transistors ST2 of the string units SU0 to SU3 are respectively connected to select gate lines SGS0 to SGS3. The string units SUs may be commonly connected to a select gate line SGS.

The control gates of the plurality of memory cells MT0 to MT7 of a block BLK are commonly connected to the respective word lines WL0 to WL7.

The drains of the select transistors ST1 of the NAND strings SR in a string unit SU are connected to respective bit lines BL0 to BL(m−1) (n is an integer that is equal to or larger than 2). Each bit line BL commonly connects NAND strings SR in the respective string units SU among the plurality of blocks BLK. The sources of the plurality of select transistors ST2 are commonly connected to a source line SL.

The string unit SU is a set of the NAND strings SR connected to the respective bit lines BL and to the same select gate lines SGD and SGS.

The block BLK is a set of a plurality of string units SU connected to the common word lines WL. The memory cell array 78 is a set of a plurality of blocks BLK connected to the common bit lines BL.

Data writing or data reading is simultaneously performed on the memory cells MT connected to a word line WL in a string unit SU. Hereinafter, a group of memory cells MT that are simultaneously selected for data writing or data reading will be referred to as a memory cell group MCG. A group of 1-bit data items written to or read from a memory cell group MCG is referred to as a page. A plurality of pages may be allocated to a memory cell group MCG.

Data can be erased in a unit of block BLK or in a unit smaller than the block BLK.

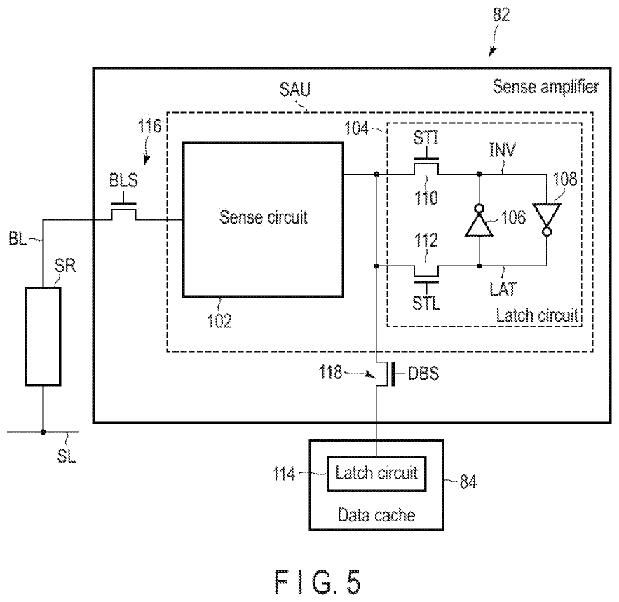

FIG. 5 is a block diagram illustrating an example of the sense amplifier 82 and the data cache 84 according to the embodiment. FIG. 5 illustrates the sense amplifier unit SAU corresponding to a bit line BL.

The sense amplifier 82 includes a plurality of sense amplifier units SAU. The sense amplifier unit SAU may be a current sensing circuit that senses current flowing through the bit line BL. Alternatively, the sense amplifier unit SAU may be a voltage sensing circuit that senses a potential of the bit line BL. The plurality of sense amplifier units SAU are respectively connected to the bit lines BL.

The sense amplifier unit SAU includes a sense circuit 102 and a latch circuit 104. In a case where the memory cell MT is a multi-level storage cell that stores 2-bit or more data, a plurality of latch circuits 104 are provided corresponding to the respective bits of multi-level data. The sense amplifier unit SAU is connected to the bit line BL via a field effect transistor 116. The sense amplifier unit SAU is connected to the latch circuit 114 in the data cache 84 via a field effect transistor 118.

For writing, the sense circuit 102 controls the potential of the bit line BL according to the data stored in the latch circuit 104. For reading, the sense circuit 102 senses the current or the potential of the bit line BL. The sense circuit 102 outputs a signal indicative of a result of the sensing to the latch circuit 104. The internal configuration of the sense circuit 102 is depends on the sensing scheme of the sense amplifier unit SAU. Detailed description of the internal configuration of the sense circuit 102 will be omitted.

The latch circuit 104 stores 1-bit data. The latch circuit 104 stores the write data WD or the read data RD. The latch circuit 104 is used for data transfer between the sense amplifier 82 and the data cache 84. The latch circuit 104 may include inverters 106 and 108 and field effect transistors 110 and 112.

The input node of the inverter 106 is connected to a node LAT. The output node of the inverter 106 is connected to a node INV. The input node of the inverter 108 is connected to the node INV. The output node of inverter 108 is connected to the node LAT. The potential stored at the node LAT may correspond to the data stored in the latch circuit 104. The potential stored at the node INV may correspond to the inverted data of the data stored at the node LAT.

The field effect transistors 110 and 112 may be n-channel MOS transistors. One of the source and the drain of the field effect transistor 110 is connected to the node INV. The other of the source and the drain of the field effect transistor 110 is connected to the output terminal of the sense circuit 102. A control signal STI is input to the gate of the field effect transistor 110. One of the source and the drain of the field effect transistor 112 is connected to the node LAT. The other of the source and the drain of the field effect transistor 112 is connected to the output terminal of the sense circuit 102. A control signal STL is input to the gate of the field effect transistor 112. Data is input to the latch circuit 104 and data is output from the latch circuit 104 based on the control signals STI and STL.

The field effect transistor 116 may be an n-channel MOS transistor of a high breakdown voltage type. The field effect transistor 116 controls the connection between the bit line BL and the sense amplifier unit SAU. One of the source and the drain of the field effect transistor 116 is connected to the bit line BL. The other of the source and the drain of the field effect transistor 116 is connected to the sense amplifier unit SAU via a wire. A control signal BLS is input to the gate of the field effect transistor 116. The control signal BLS is a signal for controlling electrical connection between the bit line BL and the sense amplifier unit SAU.

The field effect transistor 118 may be an n-channel MOS transistor of a low breakdown voltage type. The field effect transistor 118 controls the connection between the sense amplifier unit SAU and the data cache 84. One of the source and the drain of the field effect transistor 118 is connected to the output terminal of the sense circuit 102. The other of the source and the drain of the field effect transistor 118 is connected to the latch circuit 114 of the data cache 84. A control signal DBS is input to the gate of the field effect transistor 118. The control signal DBS is a signal for controlling the electrical connection between the sense amplifier unit SAU and the data cache 84. The latch circuit 114 will be described later.

The data cache 84 includes a plurality of latch circuits 114. The latch circuits 114 are respectively connected to the sense amplifier units SAU. FIG. 5 illustrates a single latch circuit 114 connected to a single sense amplifier unit SAU.

The latch circuit 114 temporarily stores the read data RD received from the sense amplifier unit SAU or the write data WD received from the input/output circuit 50. The write data WD is transferred to the sense amplifier unit SAU via the latch circuit 114. The read data RD is transferred to the input/output circuit 50 via the latch circuit 114. The circuit configuration of the latch circuit 114 may be the same as the circuit configuration of the latch circuit 104.

Next, a cache read operation according to the embodiment will be described.

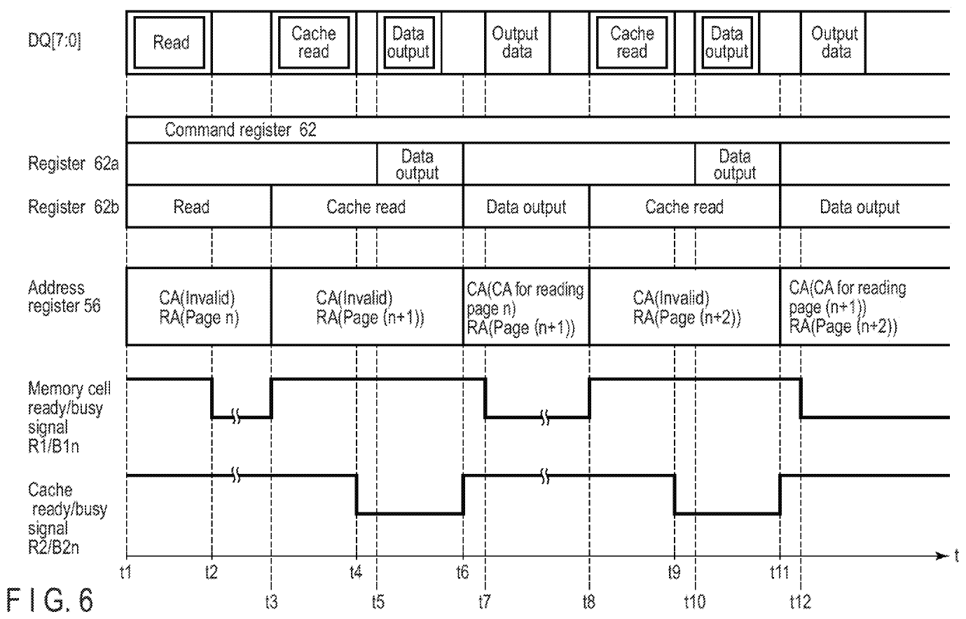

FIG. 6 is a timing chart illustrating an example of the cache read operation. It should be noted that FIG. 6 is illustrated with a scale in a direction of a time axis t set for the sake of illustration. The ratio of duration among periods (such as t1 to t2 and t2 to t3) is different from the actual ratio. For example, a command sequence transmission period is actually much shorter than a data output period.

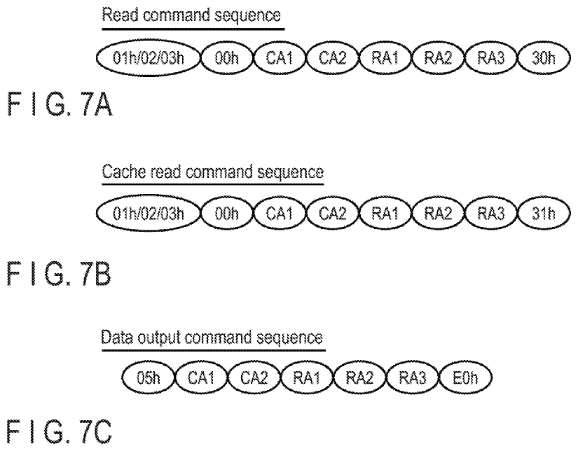

As illustrated in FIG. 6, when the host 10 requests the controller 22 for reading data, the controller 22 transmits a read command sequence (written as “read” in FIGS. 6, 14, 15, and 16), a cache read command sequence (written as “cache read” in FIGS. 6, 11, 14, 15, and 16), and data output command sequence (written as “data output” in FIGS. 6, 11, and 16) to the nonvolatile memory 24, through the I/O signals DQ [7:0]. In FIG. 6, double squares on the I/O signals DQ [7:0] indicate the command sequence, and single squares indicate output data. FIG. 7A is a diagram illustrating an example of the read command sequence. FIG. 7B is a diagram illustrating an example of the cache read command sequence. FIG. 7C is a diagram illustrating an example of the data output command sequence.

As illustrated in FIG. 7A, the read command sequence includes a command “01h/02h/03h”, command “00h”, column address CA (two column address cycles CA1 and CA2), row address RA (three row address cycles RA1, RA2 and RA3), and command “30h”. The column address CA has two cycles and the row address RA has three cycles. However, the number of cycles of the column address CA and row address RA can be set to any number depending on the number of blocks, the number of string units, and the number of bit lines of the memory cell array 78. The row address RA indicates the address of the page from which data is to be read by the read command sequence. The column address CA indicates the address of the storage location at the beginning of the data to be read within the page. In FIGS. 6, 11, 14, 15, and 16, the column address cycles CA1 and CA2 are collectively written as the column address CA, and the row address cycles RA1, RA2, and RA3 are collectively written as the row address RA.

The operation of the controller 22 for transmitting the read command sequence to the nonvolatile memory 24 will be described below.

The controller 22 transmits the command “01h/02h/03h” and the command “00h” to the nonvolatile memory 24. The controller 22 sets the signal level of the command latch enable signal CLE to the high level. The command “00h” is a command for notifying execution of data reading from the memory cell array 78. The command “00h” indicates that the read target address follows.

After transmitting the command “00h”, the controller 22 transmits the two column address cycles CA1 and CA2 and three row address cycles RA1, RA2, and RA3 to the nonvolatile memory 24. The controller 22 sets the signal level of the address latch enable signal ALE to the high level.

The controller 22 sets the address of a particular page (referred to as page n) as the row address RA. Since the column address CA is not used in the read command sequence, the controller 22 sets an invalid address for the column address CA.

After transmitting the row address cycle RA3, the controller 22 transmits the command “30h” to the nonvolatile memory 24. The controller 22 sets the signal level of the command latch enable signal CLE to the high level. The command “30h” is a command instructing execution of data reading from the memory cell array 78.

The operation of the controller 22 for transmitting the read command sequence to the nonvolatile memory 24 is as described above. Next, an operation of the nonvolatile memory 24 that has received the read command sequence will be described.

The input/output circuit 50 of the nonvolatile memory 24 transfers the read command sequence to the command register 62. The command, row address, and column address transferred to the command register 62 are input to the register 62a. At this point, since the data cache 84 is ready, the register 62a transfers the read command sequence to the register 62b instead of storing it. The register 62b stores the transferred read command sequence. The register 62b outputs the stored command, row address, and column address included in the stored read command sequence to the sequencer 68.

After receiving the command “00h” (timing t1), the sequencer 68 transmits the two column address cycles CA1 and CA2 and three row address cycles RA1, RA2, and RA3, which are received thereafter, to the address register 56. As a result, the address register 56 stores the column address CA (an invalid address) and row address RA (an address indicating page n).

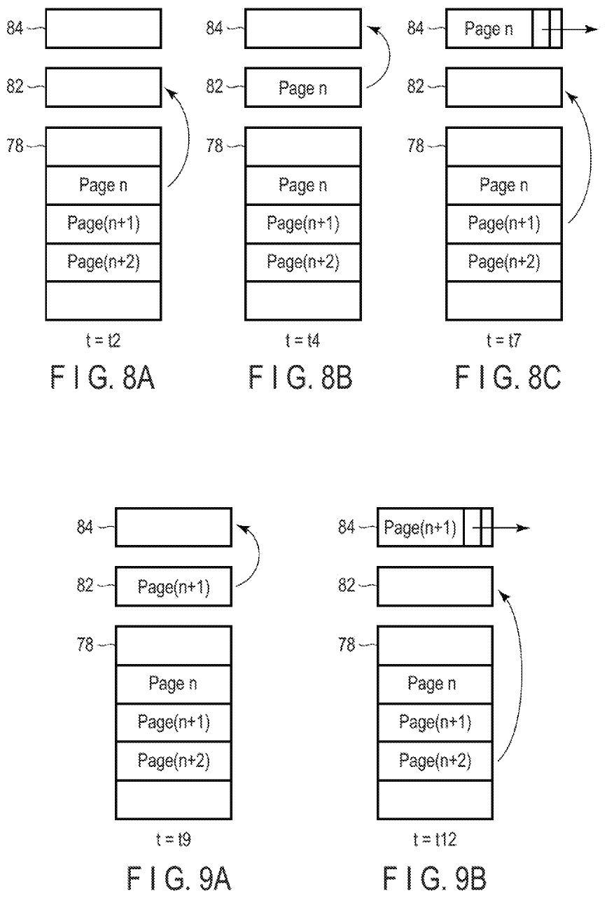

FIG. 8A is a diagram illustrating an example of a data transfer state in the nonvolatile memory 24 at timing t2 in FIG. 6. FIG. 83 is a diagram illustrating an example of a data transfer state in the nonvolatile memory 24 at timing t4 in FIG. 6. FIG. 8C is a diagram illustrating an example of a data transfer state in the nonvolatile memory 24 at timing t7 in FIG. 6.

Upon receiving the command “30h” (timing t2), the sequencer 68 starts transferring data of page n from the memory cell array 78 to the sense amplifier 82 (FIG. 8A). Page n is indicated by the result of the decoding by the row decoder 80 which decodes the row address RA stored in the address register 56. When the data transfer from the memory cell array 78 to the sense amplifier 82 starts, the memory cell array 78 becomes busy. The memory cell ready/busy signal R1/B1n changes from the high level to the low level. The sense amplifier 82 senses the data read from the memory cell array 78. The sense amplifier 82 stores the read data RD which is the sensing result, into the latch circuit 104.

The nonvolatile memory 24 executes therein (internal operation) various types of known processing for a read operation for the row address RA.

Now, an example of the internal operation of the nonvolatile memory 24 will be described. The voltage generation circuit 74 generates various voltages for a read operation, such as a read voltage. The row decoder 80 activates the selected block, the selected string unit, and the selected word line based on the row address RA. Then, the read voltage is applied to the selected word line. The number of times the read voltage is applied to the selected word line and the voltage value of the read voltage may vary depending on the address of the page to be read. The sense amplifier 82 senses the current flowing through the bit line (or the potential of the bit line). Thus, the sense amplifier 82 reads the data of the page indicated by the row address RA. The data thus read is stored into the latch circuit 104 of the sense amplifier 82.

When the data transfer for one page from the memory cell array 78 to the sense amplifier 82 is completed (timing t3), the memory cell array 78 becomes ready. The memory cell ready/busy signal R1/Bin changes from the low level to the high level. The controller 22 transmits the cache read command sequence to the nonvolatile memory 24 when the memory cell ready/busy signal R1/B1n changes from the low level to the high level.

An operation of the controller 22 for transmitting the cache read command sequence to the nonvolatile memory 24 will be described below.

As illustrated in FIG. 7B, the cache read command sequence includes a command “01h/02h/03h”, command “00h”, two column address cycles CA1 and CA2, three row address cycles RA1, RA2 and RA3, and command “31h”.

The controller 22 transmits the command “01h/02h/03h” and command “00h” to the nonvolatile memory 24. The controller 22 sets the signal level of the command latch enable signal CLE to the high level.

After transmitting the command “00h”, the controller 22 transmits the two column address cycles CA1 and CA2 and three row address cycles RA1, RA2, and RA3 to the nonvolatile memory 24. The controller 22 sets the signal level of the address latch enable signal ALE to the high level. The controller 22 sets, as the row address RA, the address of the page following the page read by the immediately preceding read command sequence executed, that is, the address indicating a page (n+1). Since the column address CA is also not used in the cache read command sequence, the controller 22 sets an invalid address for the column address CA.

After transmitting the row address cycle RA3, the controller 22 transmits the command “31h” to the nonvolatile memory 24. The controller 22 sets the signal level of the command latch enable signal CLE to the high level. The command “31h” is a command for instructing the transfer of data of one page from the sense amplifier 82 to the data cache 84 and the transfer of data of one page from the memory cell array 78 to the sense amplifier 82.

The operation of the controller 22 for transmitting the cache read command sequence to the nonvolatile memory 24 is as described above. Next, an operation of the nonvolatile memory 24 that has received the cache read command sequence will be described.

The input/output circuit 50 of the nonvolatile memory 24 transfers the cache read command sequence to the command register 62. The command, row address, and column address transferred to the command register 62 are input to the register 62a. At this timing, since the data cache 84 is ready, the register 62a transfers the cache read command sequence to the register 62b instead of storing it. The register 62b stores the transferred cache read command sequence. The register 62b outputs the command, row address, and column address included in the stored cache read command sequence to the sequencer 68.

After receiving the command “00h”, the sequencer 68 transmits the two column address cycles CA1 and CA2 and three row address cycles RA1, RA2, and RA3, which are received thereafter, to the address register 56. As a result, the address register 56 stores the column address CA (an invalid address) and row address RA (an address indicating page (n+1)).

Upon receiving the command “31h” (timing t4), the sequencer 68 starts transferring the data of page n stored in the sense amplifier 82 to the data cache 84 (FIG. 8B). When the data transfer from the sense amplifier 82 to the data cache 84 starts, the data cache 84 becomes busy. The cache ready/busy signal R2/B2n changes from the high level to the low level.

After transmitting the cache read command sequence (timing t5), the controller 22 transmits the data output command sequence to the nonvolatile memory 24.

An operation of the controller 22 for transmitting the data output command sequence to the nonvolatile memory 24 will be described below.

As illustrated in FIG. 7C, the data output command sequence includes a command “05h”, two column address cycles CA1 and CA2, three row address cycles RA1, RA2 and RA3, and command “E0h”.

The controller 22 transmits the command “05h” to the nonvolatile memory 24. The controller 22 sets the command latch enable signal CLE to the high level. The command “05h” is for notifying execution of data output from the data cache 84. The command “05h” indicates that the read target address follows.

After transmitting the command “05h”, the controller 22 transmits the two column address cycles CA1 and CA2 and three row address cycles RA1, RA2, and RA3. The controller 22 sets the signal level of the address latch enable signal. ALE to the high level. The controller 22 sets, as the column address CA, the address of the storage location at the beginning of the data to be read in page n immediately preceding page (n+1) read in the cache read command sequence. Since the row address RA is not used in the data output command sequence, the controller 22 sets an invalid address for the row address RA.

After transmitting the row address cycle RA3, the controller 22 transmits the command “E0h”. The controller 22 sets the command latch enable signal CLE to the high level. The command “E0h” is a command for instructing execution of data output from the data cache 84.

The operation of the controller 22 for transmitting the data output command sequence to the nonvolatile memory 24 is as described above. Next, an operation of the nonvolatile memory 24 that has received the data output command sequence will be described.

The input/output circuit 50 of the nonvolatile memory 24 transfers the data output command sequence to the command register 62. The command, row address, and column address transferred to the command register 62 are input to the register 62a. At this point, since the data cache 84 is busy, the register 62a stores the input command, row address, and column address instead of transferring them to the register 62b.

As described above, the data output command sequence is input to the register 62a, but is not transferred to the register 62b and thus is not output to the sequencer 68. As a result, the data output command sequence is not executed at this point. The address register 56 continues to store the column address CA (an invalid address) and row address RA (an address indicating page (n+1)) in the cache read command sequence.

When the transfer of the data of one page from the sense amplifier 82 to the data cache 84 is completed (timing t6), the data cache 84 becomes ready. The cache ready/busy signal R2/B2n changes from the low level to the high level. When the cache ready/busy signal R2/B2n changes from the low level to the high level, the register 62a transfers the data output command sequence stored therein to the register 62b. The register 62b stores the command, row address, and column address included in the transferred data output command sequence. The register 62b sequentially outputs the command, row address, and column address stored therein to the sequencer 68.

After receiving the command “05h”, the sequencer 68 transfers the column address cycles CA1 and CA2 which are received thereafter, to the address register 56. Accordingly, the column address CA of the address register 56 is changed from the column address CA included in the cache read command sequence to the column address CA included in the data output command sequence. In other words, the column address CA of the address register 56 is changed from the invalid address to the address of the storage location at the beginning of the data to be read in page n (written as “CA for reading page n” in FIG. 6). When the command “05h” is received, the sequencer 68 does not transfer the row address cycles RA1, RA2, and RA3 received thereafter, to the address register 56. As a result, the row address RA of the address register 56 remain to be the row address RA included in the cache read command sequence, that is, the address indicating page (n+1).

Upon receiving the command “E0h” (timing t7), the sequencer 68 starts outputting the read data RD of page n stored in the data cache 84. The sequencer 68 starts transferring the data of page (n+1) from the memory cell array 78 to the sense amplifier 82 (FIG. 8C). Page (n+1) is indicated by the result of the decoding by the row decoder 80 which decodes the row address RA stored in the address register 56. When the data transfer from the memory cell array 78 to the sense amplifier 82 starts, the memory cell array 78 becomes busy. The memory cell ready/busy signal R1/B1n changes from the high level to the low level. The data output start position in page n is indicated by the result of decoding by the column decoder 86 which decodes the column address CA stored in the address register 56. The column decoder 86 designates a latch circuit 114 in the data cache 84 depending on the decoding result. The controller 22 transmits the read enable signal REn at the low level after a particular period of time has elapsed since the write enable signal WEn corresponding to the command “E0h” changed from the low level to the high level. Based on the read enable signal REn at the low level, the sequencer 68 starts transmitting a part of the read data RD of page n in the data cache 84 to the controller 22 via the input/output circuit 50.

When another part of the rea data RD of the same page is to be read, the controller 22 toggles the read enable signal REn.

Then, every time the cache read command sequence and the data output command sequence are issued, operations that are the same as those in the period from timing t3 to timing t7 are performed.

The controller 22 transmits the cache read command sequence for a page (n+2) to the nonvolatile memory 24 when the memory cell ready/busy signal R1/B1n changes from the low level to the high level (timing t8).

The input/output circuit 50 of the nonvolatile memory 24 transfers the cache read command sequence to the command register 62. The command, row address, and column address transferred to the command register 62 are input to the register 62a. At this point, since the data cache 84 is ready, the register 62a transfers the input command, row address, and column address to the register 62b instead of storing them. The register 62b stores the transferred command, row address, and column address. The register 62b sequentially outputs the command, row address, and column address stored therein to the sequencer 68.

After receiving the command “00h”, the sequencer 68 transfers the two column address cycles CA1 and CA2 and three row address cycles RA1, RA2, and RA3, which are received thereafter, to the address register 56.

As a result, the address register 56 stores the column address (an invalid address) CA and row address RA (an address indicating page (n+2)) RA.

FIG. 9A is a diagram illustrating an example of a data transfer state in the nonvolatile memory 24 at timing t9 in FIG. 6. FIG. 93 is a diagram illustrating an example of a data transfer state in the nonvolatile memory 24 at timing t12 in FIG. 6.

Upon receiving the command “31h” (timing t9), the sequencer 68 starts transferring the data of page (n+1) stored in the sense amplifier 82 to the data cache 84 (FIG. 9A). When the data transfer from the sense amplifier 82 to the data cache 84 starts, the data cache 84 becomes busy. The cache ready/busy signal R2/B2n changes from the high level to the low level.

After transmitting the cache read command sequence (timing t10), the controller 22 transmits the data output command sequence to the nonvolatile memory 24.

When the transfer of the data of one page from the sense amplifier 82 to the data cache 84 is completed (timing t11), the data cache 84 becomes ready. The cache ready/busy signal R2/B2n changes from the low level to the high level. When the cache ready/busy signal R2/B2n changes from the low level to the high level, the register 62a transfers the data output command sequence stored therein to the register 62b. The register 62b stores the transferred command, row address, and column address included in the data output command sequence. The register 62b sequentially outputs the command, row address, and column address stored therein to the sequencer 68.

After receiving the command “05h”, the sequencer 68 transmits the two column address cycles CA1 and CA2 which are received thereafter, to the address register 56. As a result, the column address CA of the address register 56 is changed from the column address CA included in the cache read command sequence to the column address CA included in the data output command sequence. In other words, the column address CA of the address register 56 is changed from the invalid address to the address of the storage location at the beginning of the data to be read in page (n+1) (written as “CA for reading page (n+1)” in FIG. 6. When the command “05h” is received, the sequencer 68 does not transmit the three row address cycles RA1, RA2, and RA3 received thereafter, to the address register 56. As a result, the row address RA of the address register 56 remains to be the row address RA included in the cache read command sequence, that is, the address indicating page (n+2).

Upon receiving the command “E0h” (timing t12), the sequencer 68 starts outputting the read data RD of page (n+1) stored in the data cache 84. The sequencer 68 starts transferring the data of page (n+2) from the memory cell array 78 to the sense amplifier 82 (FIG. 9B). Page (n+2) is indicated by the result of the decoding by the row decoder 80 which decodes the row address RA stored in the address register 56. When the data transfer from the memory cell array 78 to the sense amplifier 82 starts, the memory cell array 78 becomes busy. The memory cell ready/busy signal R1/B1n changes from the high level to the low level. The data output start position in page (n+1) is indicated by the result of decoding by the column decoder 86 which decodes the column address CA stored in the address register 56.

Thereafter, every time the cache read command sequence and the data output command sequence are issued, operations that are the same as those in the period from the timing t8 to timing t12 are performed.

The nonvolatile memory 24 according to the first embodiment includes the command register 62 capable of storing two command sequences. According to the cache read command sequence, the data of page n is transferred from the sense amplifier 82 to the data cache 84, and then the data of page (n+1) is transferred from the memory cell array 78 to the sense amplifier 82. The nonvolatile memory 24 can receive the data output command sequence while the data of page (n+1) is being transferred from the memory cell array 78 to the sense amplifier 82. The received data output command sequence is stored in the command register 62 without being executed. When the data cache 84 becomes ready, the data output command sequence is output to the sequencer 68 from the command register 62, and the data of page n stored in the data cache 84 is output from the nonvolatile memory 24 while the data of page (n+1) is being transferred from the memory cell array 78 to the sense amplifier 82. Therefore, the data output command sequence is received while the cache read command sequence is being executed, whereby the reception of the data output command sequence does not impose an overhead on data output.

The specific configuration of the command register 62 is not limited to the example illustrated in FIG. 3, as long as the two command sequences can be stored. For example, the command sequence input to the command register 62 may be stored in the registers 62a or 62b which is empty. When the data output command sequence is transmitted from the controller 22 while the cache read command sequence is being stored in a register, the data output command sequence may be stored in the other register and be started when the execution of the cache read command sequence ends.

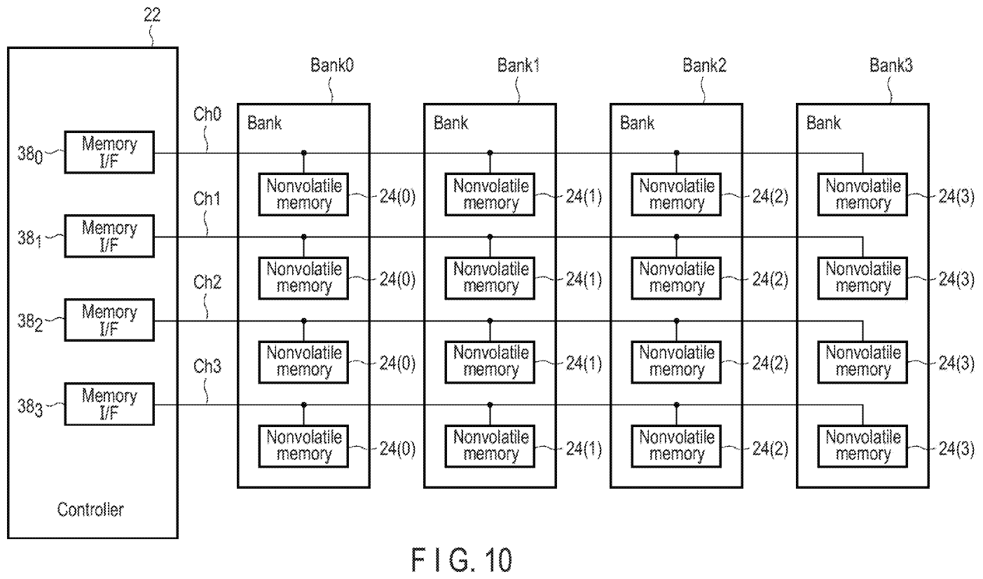

In some storage devices, a controller operates a plurality of nonvolatile memories 24 in parallel. A processing unit of the parallel operation is referred to as a bank. FIG. 10 is a block diagram illustrating an example of a storage device that performs a bank interleave operation with four banks. The controller 22 includes a plurality (four in this example) of channels Ch0, Ch1, Ch2, and Ch3, and includes memory I/Fs 380, 381, 382, and 383 for the respective channels. The controller 22 can operate a plurality (four in this example) of nonvolatile memories 24 connected to the same channel, in parallel. As an example of operating a plurality of nonvolatile memories 24 in parallel, a bank interleave operation may be employed. In the bank interleave operation, the plurality of nonvolatile memories 24 are classified into a plurality of banks. While the write, read, or erase operation is being executed on the nonvolatile memory 24 corresponding to a bank, an access for the nonvolatile memory 24 corresponding to another bank starts. In order to distinguish the components of each bank, the nonvolatile memories 24 of respective banks Bank0, Bank1, Bank2, and Bank3 and their components have (0), (1), (2), and (3) at the end of their reference numerals.

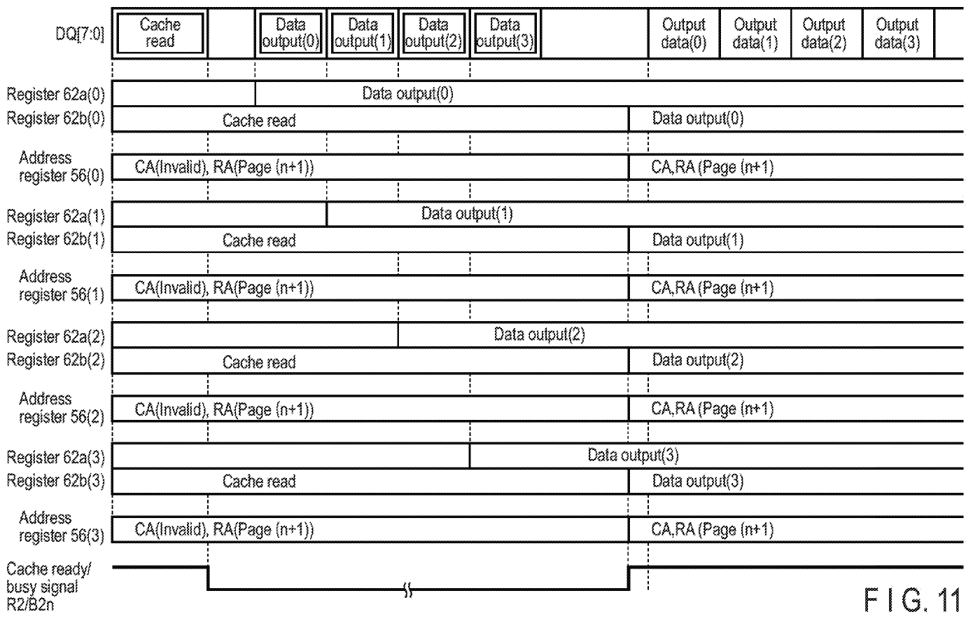

FIG. 11 is a timing chart illustrating an example of the cache read operation for a channel in a case where the first embodiment is applied to the storage device illustrated in FIG. 10. Since the operation for the read command sequence is the same as that in FIG. 6, FIG. 11 illustrates an operation from the issuance of the cache read command sequence to the output of read data.

The read command sequences and the cache read command sequences can be executed in parallel for banks Bank0 to Bank3, and are command sequences common to banks Bank0 to Bank3. The data output command sequences cannot be executed in parallel for banks Bank0 to Bank3, and are command sequences for Bank0 to Bank3, respectively.

When the controller 22 transmits the read command sequences for reading page n to the nonvolatile memories 24(0) to 24(3) in banks Bank0 to Bank3, respectively, the read command sequences are transmitted to the command registers 62(0) to 62(3), respectively. At this point, since the data caches 84 in banks Bank0 to Bank3 are ready, the registers 62b(0) to 62b(3) store the read command sequences, respectively. In banks Bank0 to Bank3, the sequencers 68 transmit the column address and row address included in the read command sequence to the address registers 56(0) to 56(3), respectively. As a result, each of the address registers 56(0) to 56(3) stores the column address CA (an invalid address) and row address RA (an address indicating page n).

In response to the commands “30h” of the read command sequences, the sequencers 68 in banks Bank0 to Bank3 cause the data of page n to be simultaneously transferred from the memory cell arrays 78 to the sense amplifiers 82, respectively. As a result, the memory cell arrays 78 in banks Bank0 to Bank3 become busy. Each of the memory cell ready/busy signals R1/Bbn in banks Bank0 to Bank3 changes from the high level to the low level.

When each of the memory cell ready/busy signals R1/Bbn changes from the low level to the high level after the read command sequences have been transmitted, the controller 22 transmits the cache read command sequences for reading page (n+1) to the nonvolatile memories 24(0) to 24(3) in banks Bank0 to Bank3, respectively. The cache read command sequences are transmitted to the command registers 62(0) to 62(3) in banks Bank0 to Bank3, respectively. At this point, since the data caches 84 in banks Bank0 to Bank3 are ready, the registers 62b(0) to 62b(3) store the cache read command sequences, respectively. In banks Bank0 to Bank3, the sequencers 68 transmit the column address and row address included in the cache read command sequence to the address registers 56(0) to 56(3), respectively. As a result, each of the address registers 56(0) to 56(3) stores the column address CA (an invalid address) and row address RA (an address indicating page (n+1)).

In response to the commands “31h” of the cache read command sequences, the sequencers 68 in banks Bank0 to Bank3 cause the data of page n stored in the sense amplifiers 82 to be transferred to the data caches 84, respectively. The sequencers 68 make the data of page (n+1) indicated by the result of the decoding by the row decoders 80 to be transferred from the memory cell arrays 78 to the sense amplifiers 82, respectively. The row decoders 80 decode the row address RA stored in of the address registers 56, respectively. When the data transfers from the sense amplifiers 82 to the data caches 84 start, the data caches 84 becomes busy. Each of the cache ready/busy signals R2/B2n changes from the high level to the low level.

After transmitting the cache read command sequences, the controller 22 transmits a data output command sequence (0), data output command sequence (1), data output command sequence (2), and data output command sequence (3) to the nonvolatile memories 24(0) to 24(3), respectively. The output command sequence (0) causes data output from the nonvolatile memory 24(0) of the bank Bank0. The data output command sequence (1) causes data output from the nonvolatile memory 24(1) of the bank Bank1. The data output command sequence (2) causes data output from the nonvolatile memory 24(2) of the bank Bank2. The data output command sequence (3) causes data output from the nonvolatile memory 24(3) of the bank Bank3. At this point, in banks Bank0 to Bank3, the data caches 84 are busy, and thus the data output command sequence (0), data output command sequence (1), data output command sequence (2), and data output command sequence (3) are stored in the command registers 62a(0) to 62a(3), respectively, and not stored in the command registers 62b(0) to 62b(3). The command registers 62b(0) to 62b(3) continue to store the cache read command sequences, respectively. Therefore, at this point, the data output command sequence (0), data output command sequence (1), data output command sequence (2), and data output command sequence (3) are not executed.

When the transfers of the data of one page from the sense amplifiers 82 to the data caches 84 in banks Bank0 to Bank3 are completed, the data caches 84 become ready. Each of the cache ready/busy signals R2/B2n changes from the low level to the high level. When the cache ready/busy signal R2/B2n changes from the low level to the high level, the command registers 62(0) to 62(3) in banks Bank0 to Bank3 transfer the data output command sequences stored by the command registers 62a(0) to 62a(3) to the command registers 62b(0) to 62b(3), respectively. The registers 62b(0) to 62b(3) store the data output command sequences thus transferred, respectively.

In banks Bank0 to Bank3, the sequencers 68 transmit the column address and row address included in the data output command sequence to the address registers 56(0) to 56(3), respectively. As a result, each of the address registers 56(0) to 56(3) stores the column address CA (column address at the time of reading page n) and row address RA (an address indicating page (n+1)).

Upon receiving the “E0h” commands included in the data output command sequences, the sequencers 68 start outputting the read data RD of page n stored in the data caches 84 in the order of the bank Bank0 to the bank Bank3. Note that the data output order of banks is not limited to this example, and may be any order.

In this manner, the cache read operation of the first embodiment can be applied to a storage device having a plurality of banks.

### Second Embodiment

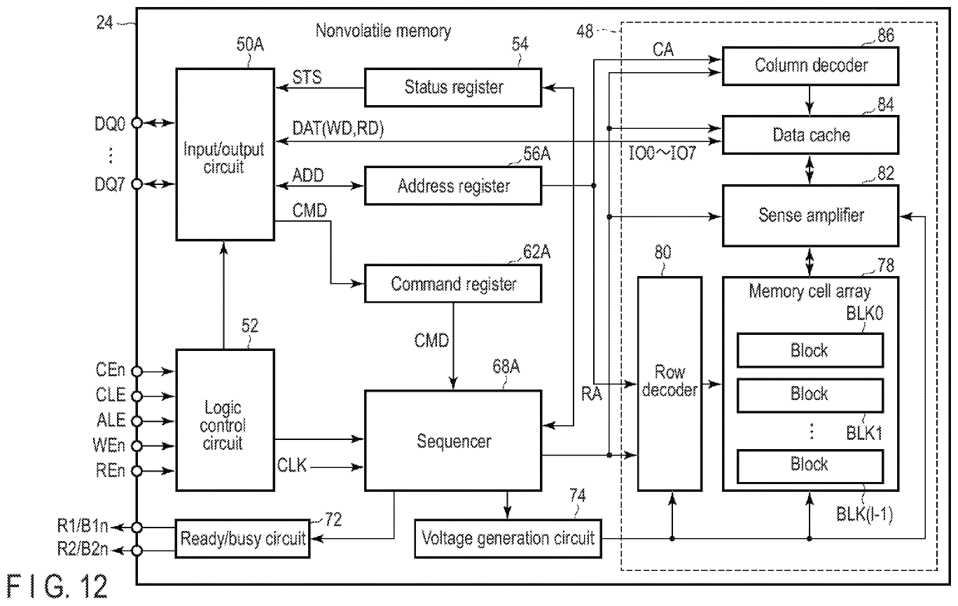

FIG. 12 is a block diagram illustrating an example of the nonvolatile memory 24 according to the second embodiment. Of the components of the nonvolatile memory 24 according to the second embodiment, components corresponding to those in the first embodiment are denoted by the same reference numerals, and detailed description thereof will be omitted.

An input/output circuit 50A sequentially transmits a plurality of commands CMD included in the command sequence received from the controller 22, to a command register 62A. The command register 62 of the first embodiment includes two registers 62a and 62b that store the command as well as the row address and column address included in two command sequences, respectively, whereas the command register 62A of the second embodiment stores one command CMD. The command register 62A stores the received command CMD. The command register 62A outputs the command CMD stored therein to a sequencer 68A.

The input/output circuit 50A sequentially transmits the column address and row address included in the command sequence received from the controller 22 to an address register 56A. The address register 56 of the first embodiment stores the column address and row address included in one command sequence, whereas the address register 56A of the second embodiment temporarily stores the column address and row address included in two command sequences received from the input/output circuit 50A.

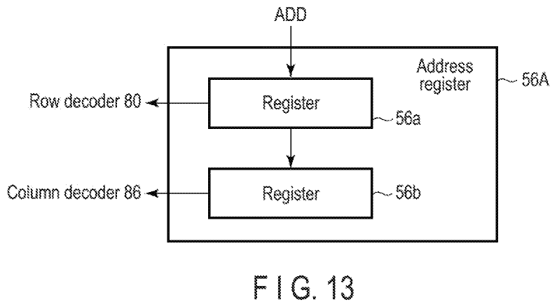

FIG. 13 is a block diagram illustrating an example of the address register 56A according to the second embodiment. The address register 56A includes registers 56a and 56b connected to form a queue. The register 56a stores the row address and column address included in one command sequence transmitted from the input/output circuit 50A. When the register 56a receives, while the register 56a is storing the column address and row address included in the one command sequence, the column address and row address included in the next command sequence, the register 56a transfers the column address and row address stored therein to the register 56b. The register 56b stores the column address and row address included in the received command sequence.

The register 56a outputs the row address RA among the addresses stored therein, to the row decoder 80. The column address CA among the addresses stored in the register 56a is not output to the column decoder 86 and is not used.

The register 56b outputs the column address CA among the addresses stored therein, to the column decoder 86. The row address RA among the addresses stored in the register 56b is not output to the row decoder 80 and is not used.

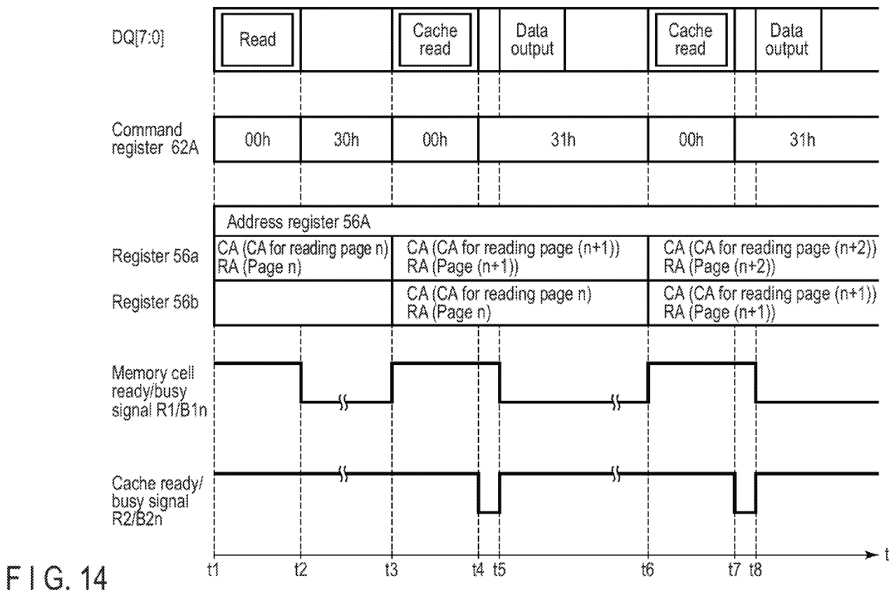

FIG. 14 is a timing chart illustrating an example of the cache read operation according to the second embodiment.

When the host 10 requests the controller 22 to read data, the controller 22 transmits the read command sequence illustrated in FIG. 7A to the nonvolatile memory 24 through the I/O signal DQ [7:0](timing t1). The input/output circuit 50A transmits a command “00h” to the command register 62A. The input/output circuit 50A transmits the two column address cycles CA1 and CA2 and three row address cycles RA1, RA2 and RA3 to the address register 56A.

The column address CA is an essential element in the read command sequence of the second embodiment. The controller 22 sets the address of a particular page (page n) as the row address RA, as in the first embodiment. The controller 22 sets, as the column address CA, the address of the storage location at the beginning of the data to be read in page n to be read in this read command sequence (written as “CA for reading page n” in FIG. 14). Therefore, the register 56a of the address register 56A stores the column address CA (CA for reading page n) and row address RA (an address indicating page n). The register 56b of the address register 56A stores a column address CA (an invalid address) and a row address RA (an invalid address).

When the input/output circuit 50A transmits the command “30h” to the command register 62A (timing t2), the sequencer 68A starts the transfer of data of page n, from a memory cell array 78 to a sense amplifier 82, in response to the command “30h”. Page n is indicated by the result of the decoding by a row decoder 80 that decodes a row address RA stored in a register 56a of the address register 56A. When the data transfer from the memory cell array 78 to the sense amplifier 82 starts, the memory cell array 78 becomes busy. The memory cell ready/busy signal R1/B1n changes from the high level to the low level.

When the data transfer for one page from the memory cell array 78 to the sense amplifier 82 is completed (timing t3), the memory cell array 78 becomes ready. The memory cell ready/busy signal. R1/B1n changes from the low level to the high level. The controller 22 transmits the cache read command sequence illustrated in FIG. 7B to the nonvolatile memory 24 when the memory cell ready/busy signal R1/B1n changes from the low level to the high level. The input/output circuit 50A transmits a command “00h” to the command register 62A. The input/output circuit 50A transmits the two column address cycles CA1 and CA2 and three row address cycles RA1, RA2 and RA3 to the address register 56A.

The column address CA is an essential element in the cache read command sequence of the second embodiment. The controller 22 sets, as the row address RA, the address of page (n+1) that is page following page n read by the read command sequence, as in the first embodiment. The controller 22 sets, as the column address CA, the address of the storage location at the beginning of the data to be read in page (n+1) to be read in this cache read command sequence (written as “CA for reading page (n+1)” in FIG. 14). Therefore, the register 56a of the address register 56A stores the column address CA (CA for reading page (n+1)) and row address RA (an address indicating page (n+1)). Therefore, the register 56b of the address register 56A stores the column address CA (CA for reading page n) and row address RA (an address indicating page n).

When the input/output circuit 50A transmits the command “31h” to the command register 62A (timing t4), the sequencer 68A transfers to the data cache 84, the data of page n stored in the sense amplifier 82, in response to the command “31h”. When the data transfer from the sense amplifier 82 to the data cache 84 starts, the data cache 84 becomes busy. The cache ready/busy signal R2/B2n changes from the high level to the low level.

When the transfer of the data from the sense amplifier 82 to the data cache 84 ends (timing t5), the data cache 84 becomes ready. The cache ready/busy signal R2/B2n changes from the low level to the high level.

The sequencer 68A starts outputting the read data RD of page n stored in the data cache 84 when the cache ready/busy signal R2/B2n changes from the low level to the high level. The data output start position of data in page n is indicated by the column address CA stored in the register 56b of the address register 56A.

When the cache ready/busy signal R2/B2n changes from the low level to the high level, the sequencer 68A also starts the transfer of the data of page (n+1) from the memory cell array 78 to the sense amplifier 82. Page (n+1) is indicated by the result of the decoding by the row decoder 80. The row decoder 80 decodes the row address RA stored in the register 56a of the address register 56A. When the data transfer from the memory cell array 78 to the sense amplifier 82 starts, the memory cell array 78 becomes busy. The memory cell ready/busy signal R1/B1n changes from the high level to the low level.

Thereafter, as in the period from the timing t1 to the timing t5, when the nonvolatile memory 24 receives the cache read command sequence for reading (n+2) (timing t6), the input/output circuit 50A outputs the command “00h” to the command register 62A. The input/output circuit 50A transmits the two column address cycles CA1 and CA2 and three row address cycles RA1, RA2 and RA3 to the address register 56A. The register 56a of the address register 56A stores the column address CA (CA for reading page (n+2)) and row address RA (an address indicating page (n+2)). Therefore, the register 56b of the address register 56A stores the column address CA (CA for reading page (n+1) and row address RA (an address indicating page (n+1)).

When the input/output circuit 50A transmits the command “31h” to the command register 62A (timing t7), the sequencer 68A transfers to the data cache 84, the data of page (n+1) stored in the sense amplifier 82, in response to the command “31h”. When the data transfer from the sense amplifier 82 to the data cache 84 starts, the data cache 84 becomes busy. The cache ready/busy signal R2/B2n changes from the high level to the low level.

When the transfer of the data from the sense amplifier 82 to the data cache 84 ends (timing t8), the data cache 84 becomes ready. The cache ready/busy signal R2/B2n changes from the low level to the high level.

The sequencer 68A starts outputting the read data RD of page (n+1) stored in the data cache 84 when the cache ready/busy signal R2/B2n changes from the low level to the high level. The data output start position of data in page n is indicated by the column address CA stored in the register 56b of the address register 56A.

When the cache ready/busy signal R2/B2n changes from the low level to the high level, the sequencer 68A also starts the transfer of the data of page (n+2) from the memory cell array 78 to the sense amplifier 82. Page (n+2) is indicated by the result of the decoding by the row decoder 80 which decodes the row address RA stored in the register 56a of the address register 56A. When the data transfer from the memory cell array 78 to the sense amplifier 82 starts, the memory cell array 78 becomes busy. The memory cell ready/busy signal R1/B1n changes from the high level to the low level.

The specific configuration of the address register 56 is not limited to the example illustrated in FIG. 13, as long as addresses included in the two command sequences can be stored. For example, the addresses included in the received command sequence may be stored in the register 56a or 56b. When the next command sequence is received while the addresses of the current command sequence are being stored in one of the register 56a or 56b, the addresses of the next command sequence may be stored in the other of the register 56a or 56b and the output of the row address and column address from the register 56a and 56b and the output of the column address and row address from the register 56a and 56b may be alternately implemented in response to the end of the command sequence execution.

The controller 22 according to the second embodiment sets, as the row address, an address of the page to be read and sets, as the column address, an address of the storage position at the beginning of the data to be read in the page to be read, in the read command sequence and the cache read command sequence. The nonvolatile memory 24 stores the addresses included in the command sequence currently being executed, in the register 56a, and stores the addresses included in the command sequence immediately previously executed, in the register 56b. When the data transfer from the sense amplifier 82 to the data cache 84 by the cache read command “31h” ends, the sequencer 68A causes the data indicated by the column address stored in the register 56b of the address register 56A to be output from the data cache 84. As a result, the cache read operation can be executed without requiring the data output command sequence. Therefore, the overhead can be further reduced from that in the case of the first embodiment.

### Third Embodiment

The nonvolatile memory 24 of the third embodiment is the same as the nonvolatile memory 24 of the second embodiment except for the configuration of the address register. The circuit diagram of the nonvolatile memory 24 is the same as that in FIG. 12, and thus will not be illustrated. The address register 56A of the second embodiment has two registers and stores the addresses included in the two command sequences, whereas the address register 56 of the third embodiment has a register to store addresses included in the command sequence as in the first embodiment.

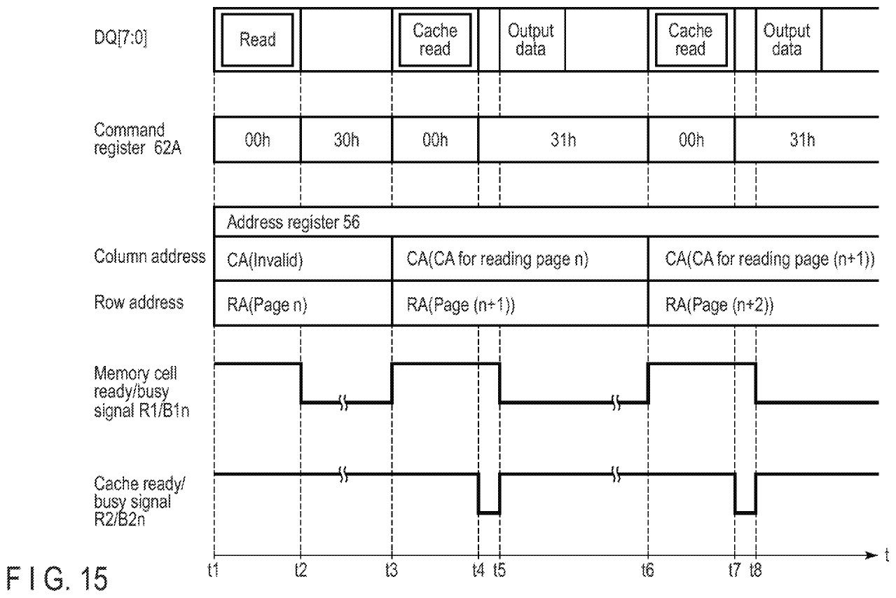

FIG. 15 is a timing chart illustrating an example of the cache read operation according to the third embodiment.

When the host 10 requests the controller 22 to read data, the controller 22 transmits the read command sequence illustrated in FIG. 7A to the nonvolatile memory 24 through an I/O signal DQ [7:0] (timing t1). An input/output circuit 50A transmits a command “00h” to a command register 62A. The input/output circuit 50A transmits the two column address cycles CA1 and CA2 and three row address cycles RA1, RA2, and RA3 to the address register 56.

In the third embodiment, since the column address CA is not used in the read command sequence, the controller 22 sets invalid address for the column address CA as in the first embodiment. In the read command sequence, the controller 22 sets the address of a particular page (page n) as the row address RA, as in the first embodiment. As a result, the address register 56 stores the column address CA (an invalid address) and row address RA (an address indicating page n).

When the input/output circuit 50A transmits the command “30h” to the command register 62A (timing t2), the sequencer 68A starts the transfer of the data of page n from a memory cell array 78 to a sense amplifier 82, in response to the command “30h”. Page n is indicated by the result of the decoding by the row decoder 80 which decodes the row address RA stored in the address register 56. When the data transfer from the memory cell array 78 to the sense amplifier 82 starts, the memory cell array 78 becomes busy. The memory cell ready/busy signal R1/B1n changes from the high level to the low level.

When the data transfer for one page from the memory cell array 78 to the sense amplifier 82 is completed (timing t3), the memory cell array 78 becomes ready. The memory cell ready/busy signal R1/B1n changes from the low level to the high level. The controller 22 transmits the cache read command sequence illustrated in FIG. 7B to the nonvolatile memory 24 when the memory cell ready/busy signal R1/B1n changes from the low level to the high level. The input/output circuit 50A transmits a command “00h” to the command register 62A. The input/output circuit 50A transmits the two column address cycles CA1 and CA2 and three row address cycles RA1, RA2, and RA3 to the address register 56.

The column address CA is an essential element in the cache read command sequence of the third embodiment. For example, the controller 22 sets, as the row address RA, the address of page (n+1) that is the page following the page read 5y the read command sequence. The controller 22 sets, as the column address CA, the address of the storage location at the beginning of the data to be read in page n (that is, the page that has been read by the read command sequence) preceding page (n+1) to be read in this cache reading (written as “CA for reading page n” in FIG. 15). Therefore, the address register 56 stores the column address CA (CA for reading page n) and row address RA (an address indicating page (n+1)).

When the input/output circuit 50A transmits the command “31h” to the command register 62A (timing t4), the sequencer 68A transfers to the data cache 84, the data of page n stored in the sense amplifier 82, in response to the command “31h”. When the data transfer from the sense amplifier 82 to the data cache 84 starts, the data cache 84 becomes busy. The cache ready/busy signal R2/B2n changes from the high level to the low level.

When the transfer of the data from the sense amplifier 82 to the data cache 84 ends (timing t5), the data cache 84 becomes ready. The cache ready/busy signal R2/B2n changes from the low level to the high level.

The sequencer 68A starts outputting the read data RD of page n stored in the data cache 84 when the cache ready/busy signal R2/B2n changes from the low level to the high level. The data output start position of data in page n is indicated by the column address CA stored in the address register 56.

When the cache ready/busy signal R2/B2n changes from the low level to the high level, the sequencer 68A also starts the transfer of the data of page (n+1) from the memory cell array 78 to the sense amplifier 82. Page (n+1) is indicated by the result of the decoding by the row decoder 80 which decodes the row address RA stored in the address register 56. When the data transfer from the memory cell array 78 to the sense amplifier 82 starts, the memory cell array 78 becomes busy. The memory cell ready/busy signal R1/B1n changes from the high level to the low level.

Thereafter, as in the period from timing t3 to timing t5, when the nonvolatile memory 24 receives the cache read command sequence for reading page (n+2) (timing t6), the input/output circuit 50A outputs the command “00h” to the command register 62A. The input/output circuit 50A transmits the two column address cycles CA1 and CA2 and three row address cycles RA1, RA2, and RA3 to the address register 56. Therefore, the address register 56 stores the column address CA (CA for reading page (n+1)) and row address RA (an address indicating page (n+2)).

When the input/output circuit 50A transmits the command “31h” to the command register 62A (timing t7), the sequencer 68A transfers to the data cache 84, the data of page (n+1) stored in the sense amplifier 82, in response to the command “31h”. When the data transfer from the sense amplifier 82 to the data cache 84 starts, the data cache 84 becomes busy. The cache ready/busy signal R2/B2n changes from the high level to the low level.

When the transfer of the data from the sense amplifier 82 to the data cache 84 ends (timing t8), the data cache 84 becomes ready. The cache ready/busy signal R2/B2n changes from the low level to the high level.

The sequencer 68A starts outputting the read data RD of page (n+1) stored in the data cache 84 when the cache ready/busy signal R2/B2n changes from the low level to the high level. The data output start position of data in page n is indicated by the column address CA stored in the address register 56.

When the cache ready/busy signal R2/B2n changes from the low level to the high level, the sequencer 68A also starts the transfer of the data of page (n+2) from the memory cell array 78 to the sense amplifier 82. Page (n+2) is indicated by the result of the decoding by the row decoder 80 that decodes the row address RA stored in the address register 56. When the data transfer from the memory cell array 78 to the sense amplifier 82 starts, the memory cell array 78 becomes busy. The memory cell ready/busy signal R1/B1n changes from the high level to the low level.

The controller 22 according to the third embodiment sets, as the row address, an address of the page to be read and sets, as the column address, an address of the storage position at the beginning of the data to be read in the page preceding the page to be read, in the cache read command sequence. The nonvolatile memory 24 stores the addresses included in the command sequence currently being executed, in the register 56. When the data transfer from the sense amplifier 82 to the data cache 84 by the cache read command “31h” ends, the sequencer 68A causes the data indicated by the column address stored in the address register 56 to be output from the data cache 84. As a result, the cache read operation can be executed without requiring the data output command sequence. Therefore, the overhead can be further reduced from that in the case of the first embodiment. Furthermore, the size of the address register 56 can be 50% of that in the second embodiment.

### Fourth Embodiment

The first embodiment, the second embodiment, and the third embodiment relate to the nonvolatile memory 24 with a single plane structure. The first embodiment, the second embodiment, and the third embodiment are also applicable to a nonvolatile memory with a multi-plane structure. A fourth embodiment is described as an example in which the cache read operation according to the third embodiment is applied to a nonvolatile memory having a two-plane structure. A fourth embodiment may be implemented by applying the cache read operation according to the first or second embodiment to a nonvolatile memory having a two-plane structure. The nonvolatile memory with the two-plane structure are similar to the nonvolatile memory 24 of the first embodiment illustrated in FIG. 2 or the nonvolatile memory 24 of the second embodiment illustrated in FIG. 12, and thus the circuit diagram thereof will not be provided. The nonvolatile memory 24 of the fourth embodiment is obtained by providing two planes 48 in the nonvolatile memory 24 illustrated in FIG. 12. The two planes 46 are connected in parallel with the input/output circuit 50, status register 54, address register 56, command register 62, sequencer 68, and the like. The ready/busy circuit 72 outputs a signal for each plane. The ready/busy circuit 72 outputs a memory cell ready/busy signal R1/B1n(A) and the cache ready/busy signal R2/B2n(A) for the plane A, and a memory cell/busy signal R1/B1n(B) and a cache ready/busy signal R2/B2n(B) for the plane B.

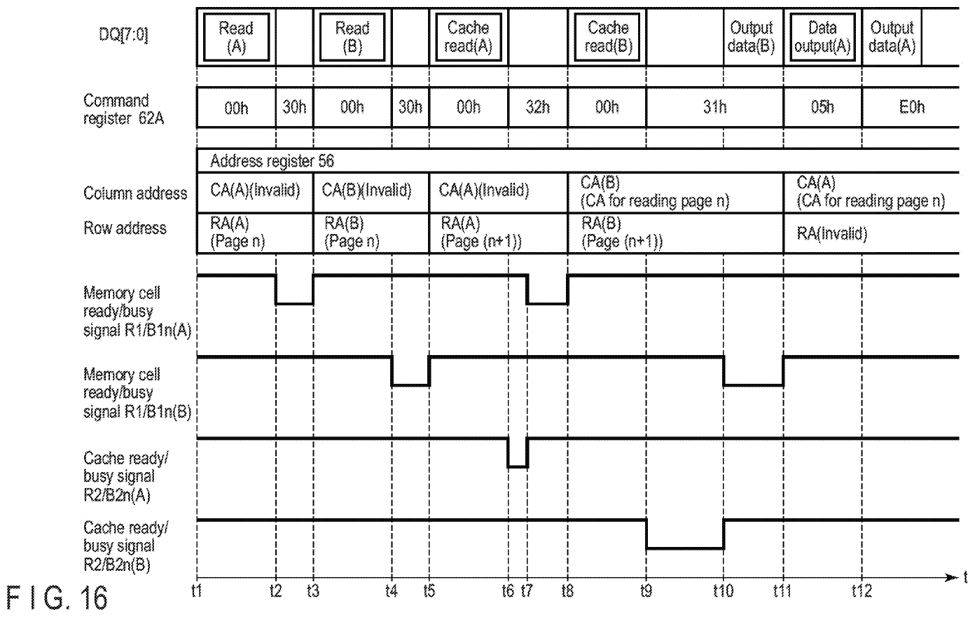

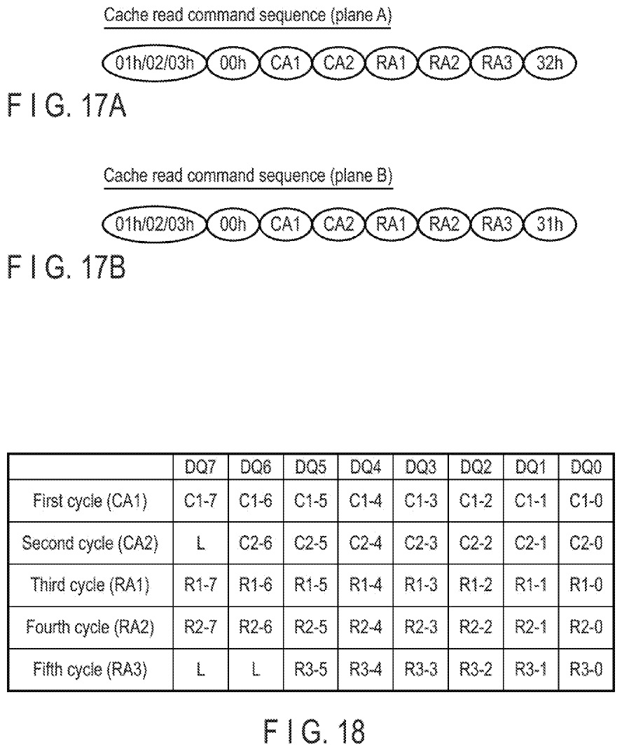

FIG. 16 is a timing chart illustrating an example of the cache read operation according to the fourth embodiment. FIG. 17A is a diagram illustrating an example of the cache read command sequence for the plane A in FIG. 16. The cache read command sequence for the plane A is the same as the cache read command sequence illustrated in FIG. 7B, except that the last command “31h” illustrated in FIG. 7B is changed to another command “32h”. FIG. 17B is a diagram illustrating an example of the cache read command sequence for the plane B in FIG. 16. The cache read command sequence for the plane B is the same as the cache read command sequence illustrated in FIG. 7B. When the host 10 requests the controller 22 to read data for the plane A and plane B (timing t1), the controller 22 transmits the read command sequence for the plane A as illustrated in FIG. 7A (written as “read (A” in FIG. 16) to the nonvolatile memory 24 through the I/O signal DQ [7:0]. The input/output circuit 50A transmits the command “00h” to the command register 62A. The input/output circuit 50A transmits the two column address cycles CA1 and CA2 and three row address cycles RA1, RA2, and RA3 to the address register 56.

In the read command sequence of the fourth embodiment (for both the plane A and the plane B), the column address CA is not used, and thus the controller 22 sets the column address CA of the plane A (written as “CA(A)” in FIG. 16) to be an invalid address. In the read command sequence (for both the plane A and the plane B), the controller 22 sets an address indicating a particular page (page n) as the row address RA (written as “RA(A)” in FIG. 16). Therefore, the address register 56 stores the column address CA(A) (an invalid address) of the plane A and row address RA(A) (an address indicating page n) of the plane A.

When the input/output circuit 50A transmits the command “30h” to the command register 62A (timing t2), the sequencer 68A starts transferring data of page n for the plane A from the memory cell array 78 to the sense amplifier 82, in response to the command “30h”. Page n for the plane A is indicated by the result of the decoding by the row decoder 80 of the plane A which decodes row address RA(A) stored 5y the address register 56. When the data transfer from the memory cell array 78 to the sense amplifier 82 starts in the plane A, the memory cell array 78 in the plane A becomes busy. The memory cell ready/busy signal R1/B1n(A) for the plane A changes from the high level to the low level.

In the plane A, when the data transfer for one page from the memory cell array 78 to the sense amplifier 82 is completed (timing t3), the memory cell array 78 becomes ready. The memory cell ready/busy signal R1/B1n(A) for the plane A changes from the low level to the high level. The controller 22 transmits the read command sequence for the plane B as illustrated in FIG. 7A (written as read (B) in FIG. 16) to the nonvolatile memory 24, when the memory cell ready/busy signal R1/B1n(A) for the plane A changes from the low level to the high level. The input/output circuit 50A transmits the command “00h” to the command register 62A, and transmits the two column address cycles CA1 and CA2 and three row address cycles RA1, RA2, and RA3 to the address register 56. As a result, the address register 56 stores the column address CA(B) (an invalid address) of the plane B and row address RA(B) (an address indicating page n) of the plane B.

When the input/output circuit 50A transmits the command “30h” to the command register 62A (timing t4), the sequencer 68A starts the transfer of the data of page n for the plane B from memory cell array 78 to the sense amplifier 82, in response to the command “30h”. Page n for the plane B is indicated by the result of the decoding by the row decoder 80 of the plane B that decodes the row address RA(B) stored in the address register 56. When data transfer from the memory cell array 78 to the sense amplifier 82 starts in the plane B, the memory cell array 78 in the plane B becomes busy. The memory cell ready/busy signal R1/B1n(B) for the plane B changes from the high level to the low level.

In the plane B, when the data transfer for one page from the memory cell array 78 to the sense amplifier 82 is completed (timing t5), the memory cell array 78 becomes ready. The memory cell ready/busy signal R1/B1n(B) for the plane B changes from the low level to the high level. The controller 22 transmits the cache read command sequence for the plane A as illustrated in FIG. 17A (written as “cache read (A)” in FIG. 16) to the nonvolatile memory 24, when the memory cell ready/busy signal R1/B1n(B) for the plane B changes from the low level to the high level. The input/output circuit 50A transmits a command “00h” to the command register 62A. The input/output circuit 50A transmits the two column address cycles CA1 and CA2 and three row address cycles RA1, RA2, and RA3 to the address register 56.

In the cache read command sequence for the plane A of the fourth embodiment, the controller 22 sets, as the row address RA, an address indicating page (page (n+1)) to be read after the page (page n) read in the read command sequence. The controller 22 sets an invalid address as the column address CA. As a result, the address register 56 stores the column address CA(A) (an invalid address) and row address RA(A) (an address indicating page (n+1)).

When the input/output circuit 50A transmits the command “32h” to the command register 62A (timing t6), the sequencer 68A transfers to the data cache 84, the data of page n stored in the sense amplifier 82 of the plane A, in response to the command “32h”. In the plane A, when the data transfer from the sense amplifier 82 to the data cache 84 starts, the data cache 84 becomes busy. The cache ready/busy signal R2/B2n(A) for the plane A changes from the high level to the low level.

In the plane A, when the transfer of the data of page n from the sense amplifier 82 to the data cache 84 is completed (timing t7), the data cache 84 becomes ready. The cache ready/busy signal R2/B2n(A) for the plane A changes from the low level to the high level.

When the cache ready/busy signal R2/B2n(A) of the plane A changes from the low level to the high level, the sequencer 68A starts the transfer of the data of page (n+1) from the memory cell array 78 to the sense amplifier 82. Page (n+1) is indicated by the result of the decoding by the row decoder 80 of the plane A which decodes the row address RA(A) stored in the address register 56. When the data transfer from the memory cell array 78 to the sense amplifier 82 starts, the memory cell array 78 becomes busy. The memory cell ready/busy signal R1/B1n(A) of the plane A changes from the high level to the low level.

In the plane A, when the data transfer for page (n+1) from the memory cell array 78 to the sense amplifier 82 is completed (timing t8), the memory cell array 78 becomes ready. The memory cell ready/busy signal R1/B1n (A) of the plane A changes from the low level to the high level. The controller 22 transmits the cache read command sequence for the plane B as illustrated in FIG. 17B (written as “cache read (B)” in FIG. 16) to the nonvolatile memory 24, when the memory cell ready/busy signal R1/B1n(A) for the plane A changes from the low level to the high level. The input/output circuit 50A transmits the command “00h” to the command register 62A. The input/output circuit 50A transmits the two column address cycles CA1 and CA2 and three row address cycles RA1, RA2, and RA3 to the address register 56.

In the cache read command sequence for the plane B of the fourth embodiment, the controller 22 sets, as the row address RA, an address indicating page (page (n+1)) to be read after the page read in the read command sequence. The controller 22 sets, as the column address CA, the address of the storage location at the beginning of the data to be read in the page (page n) that has been read by the read command sequence (written as “CA for reading page n” in FIG. 16). Therefore, the address register 56 stores the column address CA(B) (CA for reading page n) and row address RA(B) (an address indicating page (n+1)).

When the input/output circuit 50A transmits the command “31h” to the command register 62A (timing t9), the sequencer 68A transfers to the data cache 84, the data of page n stored in the sense amplifier 82 of the plane B, in response to the command “31h”. In the plane B, when the data transfer from the sense amplifier 82 to the data cache 84 starts, the data cache 84 becomes busy. The cache ready/busy signal R2/B2n(B) of the plane B changes from the high level to the low level.

In the plane B, when the data transfer from the sense amplifier 82 to the data cache 84 is completed (timing t10), the data cache 84 becomes ready. The cache ready/busy signal R2/B2n(B) of the plane B changes from the low level to the high level.

When the cache ready/busy signal R2/B2n(B) of the plane B changes from the low level to the high level, the sequencer 68A starts outputting the read data RD of page n stored in the data cache 84. The data output start position in page n is indicated by the result of decoding by the column decoder 86 which decodes the column address CA(B) stored in the address register 56.

When the cache ready/busy signal R2/B2n(B) of the plane B changes from the low level to the high level, the sequencer 68A also starts the transfer of the data of page (n+1) for the plane B from the memory cell array 78 to the sense amplifier 82. Page (n+1) for the plane B is indicated by the result of the decoding by the row decoder 80 of the plane B which decodes the row address RA(B) stored in the address register 56. When data transfer from the memory cell array 78 to the sense amplifier 82 starts in the plane B, the memory cell array 78 becomes busy. The memory cell ready/busy signal R1/B1n(B) of the plane B changes from the high level to the low level.

When the data transfer for page (n+1) from the memory cell array 78 to the sense amplifier 82 is completed for the plane B (timing t11), the memory cell array 78 becomes ready. The memory cell ready/busy signal R1/B1n(B) of the plane B changes from the low level to the high level. When the memory cell ready/busy signal R1/B1n(B) of the plane B changes from the low level to the high level, the controller 22 transmits the data output sequence for the plane A as illustrated in FIG. 7C.

The input/output circuit 50A transmits the command “05h” to the command register 62A. The input/output circuit 50A transmits the two column address cycles CA1 and CA2 and three row address cycles RA1, RA2, and RA3 to the address register 56.

Since the row address RA is not used in the data output command sequence, the controller 22 sets an invalid address for the row address RA. The controller 22 sets, as the column address CA, the address of the first storage location of the data to be read in page n immediately preceding page (n+1) that has been read by the previous cache read for the plane A (written as “CA for reading page n” in FIG. 16). Therefore, the address register 56 stores the column address CA(A) (CA for reading page n) and row address RA(A) (an invalid address).

When the input/output circuit 50A transmits the command “E0h” to the command register 62A (timing t12), the sequencer 68A starts outputting the read data RD of page n stored in the data cache 64 of the plane A, in response to the command “E0h”. The data output start position in page n is indicated by the result of decoding by the column decoder 86 of the plane A which decodes the column address CA(A) stored in the address register 56.

As described above, also in the nonvolatile memory 24 with a multi-plane structure, the cache read operation can be executed without requiring the data output command sequence for a single plane.

In the cache read operation of FIG. 16, the data output for the second plane (plane B) transmitted later by the controller 22 is executed earlier, and the data output for the first plane (plane A) transmitted first is executed later.

A modification will be described in which the plane for which data output is executed first can be selected regardless of the order of transmission by the controller 22. The cache read command sequence for the first and second planes transmitted by the controller 22 is the same as those illustrated in FIGS. 17A and 17B. However, the addresses included in the cache read command sequence are different from those in the fourth embodiment. FIG. 18 illustrates an example of addresses included in the cache read command sequence for the first plane transmitted earlier by the controller 22.

A column address CA1 in the first cycle is an 8-bit address. The bit 0 to bit 7 of the column address CA1 in the first cycle are respectively transmitting column addresses C1-0 to C1-7 of the bit 0 to bit 7. A column address CA2 in the second cycle is a 7-bit address. The bit 0 to bit 6 of the column address CA2 in the second cycle are respectively transmitting column addresses C2-0 to C2-6 of the bit 0 to bit 6. The bit 7 of column address CA2 (denoted by L in FIG. 18) is not used. A row address RA1 in the third cycle is an 8-bit address. The bit 0 to bit 7 of the row address RA1 in the third cycle are respectively transmitting row addresses R1-0 to R1-7 of the bit 0 to bit 7. A row address RA2 of the fourth cycle is an 8-bit address. The bit 0 to bit 7 of the row address RA2 in the fourth cycle are respectively transmitting row addresses R2-0 to R2-7 of the bit 0 to bit 7. A row address RA3 in the fifth cycle is a 6-bit address. The bit 0 to bit 5 of the row address RA3 of the fifth cycle are respectively transmitting row addresses R3-0 to C3-5 of the bit 0 to bit 5. The bits 6 and 7 of the row address RA2 are not used (denoted by L in FIG. 18).

As described above, the row address and the column address in the cache read command sequence for the first plane transmitted first by the controller 22 include an unused bit. This unused bit can be used to designate the plane for which the data output is executed first.

The controller 22 sets an unused bit in the cache read command sequence for the first plane (may be the bit 7 in the column address CA2, or the bit 6 or the bit 7 in the row address RA2) in accordance with the plane for which the data output is to be executed first. For example, when the data output for the plane A is to be executed before the data output for the plane B, the controller 22 sets the unused bit in the cache read command sequence for the first plane to be “0”. The controller 22 sets the address in the cache read command sequence of the first plane, as illustrated in FIG. 16. That is, the controller 22 sets an address indicating page (n+1) as the row address RA. The controller 22 sets an invalid address as the column address CA.

The controller 22 sets, as the address in the cache read command sequence for the second plane to be transmitted second, the address used in the cache read command sequence for the plane for which data output is to be executed first. For example, when the data output for plane A is to be executed before the data output for plane B, the controller 22 sets the address indicating page (n+1) as the row address RA, and sets an invalid address as the column address CA in the cache read command sequence for the second plane.

On the other hand, when the data output for the plane B is to be executed before the data output for the plane A, the controller 22 sets the unused bit in the cache read command sequence for the first plane to be “1”. The controller 22 transmits a command sequence similar to that in the fourth embodiment as the cache read command sequence for the first plane and the second plane.

When such a cache read command sequence is received by the nonvolatile memory 24, the address register 56A recognizes the plane for which the data output is to be executed first, based on “0” or “1” of the unused bit of the first plane. Then, according to the recognition result, the address included in the cache read command sequence fox the second plane is processed as the address of the plane for which data output is to be executed first.

There are three unused bits, and at least two of them are used, so that the plane for which the data output is to be executed first can be indicated even when the number of the multi-plane increases or even when the number of planes in the multi-plane structure nonvolatile memory 24 increases to be four or more.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A storage device comprising:
a memory cell array configured to store data;
a control circuit configured to process the data stored in the memory cell array in accordance with a command transmitted from a controller; and
a command register configured to store a first command and a second command transmitted from the controller.

2. The storage device of claim 1, wherein
in a case where the second command is transmitted from the controller while the control circuit executes a first operation designated by the first command, and the second command is stored in the command register, the control circuit is configured not to execute a second operation designated by the second command while executing the first operation, and execute the second operation after the execution of the first operation is completed.

3. The storage device of claim 1, wherein
the command register comprises a first register configured to store the first command or the second command and a second register configured to store the first command or the second command,
the control circuit is configured to execute a first operation designated by the first command stored in the second register or a second operation designated by the second command stored in the second register, and
in a case where the second register stores the first command, and the second command is transmitted from the controller while the control circuit executes the first operation, the first register is configured to store the second command, and the first register is configured to transfer the second command to the second register to make the second register store the second command after an execution of the first operation is completed.

4. The storage device of claim 2, further comprising:
a first latch circuit configured to store data read from the memory cell array;
a second latch circuit configured to store data read from the first latch circuit; and
an address register configured to store a first address of data relating to the first operation and a second address of data relating to the second operation, wherein
the address register is configured to store the first address while the first operation is executed,
the address register is configured to store the second address after an execution of the first operation is completed,
the first operation comprises transferring first data from the first latch circuit to the second latch circuit, and transferring second data designated by the first address from the memory cell array to the first latch circuit, and
the second operation comprises transferring third data designated by a part of the second address from the second latch circuit to the controller, and transferring fourth data designated by another part of the second address from the memory cell array to the first latch circuit.

5. The storage device of claim 4, wherein the control circuit is configured to start the second operation when the second latch circuit changes from busy to ready.

6. A storage device comprising:
a memory cell array configured to store data;
a control circuit configured to process the data stored in the memory cell array in accordance with a command transmitted from a controller; and
an address register configured to store a first address of data relating to a first operation designated by a first command, and a second address of data relating to a second operation designated by a second command.

7. The storage device of claim 6, wherein
the address register comprises a first register configured to store the first address or the second address and a second register configured to store the first address or the second address, and
in a case where the second address is transmitted from the controller while the first register is storing the first address, the first register is configured to store the second address after transferring the first address to the second register, and the second register is configured to store the first address.

8. The storage device of claim 7, further comprising:
a first latch circuit configured to store data read from the memory cell array; and
a second latch circuit configured to store data read from the first latch circuit, wherein
the control circuit is configured to transfer first data from the first latch circuit to the second latch circuit, transfer second data designated by the second address stored in the first register from the memory cell array to the first latch circuit, and transfer data designated by the first address stored in the second register from the second latch circuit to the controller.

9. The storage device of claim 6, further comprising:
a first latch circuit configured to store data read from the memory cell array; and
a second latch circuit configured to store data read from the first latch circuit, wherein
the control circuit is configured to transfer first data from the first latch circuit to the second latch circuit, transfer second data designated by the second address stored in the address register from the memory cell array to the first latch circuit, and transfer data designated by the first address stored in the address register from the second latch circuit to the controller.

10. A method for a system comprising a storage device and a controller, the storage device comprising a memory cell array configured to store data and a control circuit configured to process the data stored in the memory cell array in accordance with a command transmitted from the controller, the method comprising:
transmitting a first command to the storage device by the controller;
storing the first command into a first command register by the storage device;
executing a first operation designated by the first command by the storage device;
transmitting a second command to the storage device by the controller before the execution of the first operation is completed;
storing the second command into a second command register by the storage device;
transferring the second command from the second command register to the first command register by the storage device in a case where the execution of the first operation is completed; and
storing the second command into the first command register by the storage device.

11. A method for a system comprising a storage device and a controller, the storage device comprising a memory cell array configured to store data and a control circuit configured to process the data stored in the memory cell array in accordance with a command transmitted from the controller, the method comprising:
transmitting a command to the storage device by the controller;
storing a first address and a second address included in the command into an address register by the storage device;
reading data designated by the first address from the memory cell array by the storage device; and
reading data designated by the second address from the memory cell array by the storage device.

12. The method of claim 11, wherein
the address register comprises a first register configured to store the first address or the second address and a second register configured to store the first address or the second address, and
in a case where the second address is transmitted from the controller while the first register is storing the first address, the first register is configured to store the second address after transferring the first address to the second register, and the second register is configured to store the first address.

13. The method of claim 12, wherein the storage device further comprises:
a first latch circuit configured to store data read from the memory cell array; and
a second latch circuit configured to store data read from the first latch circuit, wherein
the control circuit is configured to transfer first data from the first latch circuit to the second latch circuit, transfer second data designated by the second address stored in the first register from the memory cell array to the first latch circuit, and transfer data designated by the first address stored in the second register from the second latch circuit to the controller.

14. The method of claim 11, wherein the storage device further comprises:
a first latch circuit configured to store data read from the memory cell array; and
a second latch circuit configured to store data read from the first latch circuit, wherein
the control circuit is configured to transfer first data from the first latch circuit to the second latch circuit, transfer second data designated by the second address stored in the address register from the memory cell array to the first latch circuit, and transfer data designated by the first address stored in the address register from the second latch circuit to the controller.
